(19) United States
(12) Patent Application Publication
(10) Pub. No.: US 2006/0269782 A1
(43) Pub. Date: Nov. 30, 2006

(54) OLED electron-transporting layer

(75) Inventors: Liang-Sheng Liao, Rochester, NY (US); Scott R. Conley, Rochester, NY (US); Lelia Cosimbescu, Rochester, NY (US); Viktor V. Jarikov, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/136,768

(22) Filed: May 25, 2005

(51) Int. Cl. H01L 51/54; H05B 33/12

(52) U.S. Cl. 428/690; 428/917; 313/504; 313/506; 257/E51.049

(57) ABSTRACT

An organic light-emitting device (OLED) includes an anode, a cathode, and a light-emitting layer disposed between the anode and the cathode, wherein the light-emitting layer includes a dominant host and a dopant. The device also includes an electron-transporting layer disposed in direct contact with the light-emitting layer on the cathode side, wherein the electron-transporting layer includes an electron-transporting material having the same chromophore as that of the dominant host in the light-emitting layer, wherein the electron-transporting material constitutes more than 50% by volume of the electron-transporting layer, and wherein the electron-transporting material has a greater reduction potential than that of the dominant host in the light-emitting layer.

### FIELD OF INVENTION

This invention relates to organic light-emitting device (OLED). More specifically, this invention relates to OLED having an electron-transporting layer to improve the electroluminescence (EL) performance of the device.

### BACKGROUND OF THE INVENTION

OLEDs, as described by Tang in commonly assigned U.S. Pat. No. 4,356,429, are commercially attractive because they offer the promise of low cost fabrication of high density pixel displays exhibiting bright EL with long lifetime, high luminous efficiency, low drive voltage, and wide color range.

A typical OLED includes two electrodes and one organic EL unit disposed between the two electrodes. The organic EL unit commonly includes an organic hole-transporting layer (HTL), an organic light-emitting layer (LEL), and an organic electron-transporting layer (ETL). One of the electrodes is the anode, which is capable of injecting positive charges (holes) into the HTL of the EL unit. The other electrode is the cathode, which is capable of injecting negative charges (electrons) into the ETL of the EL unit. When the anode is biased with a certain positive electrical potential relative to the cathode, holes injected from the anode and electrons injected from the cathode can recombine and emit light from the LEL. At least one of the electrodes is optically transmissive, and the emitted light is seen through the transmissive electrode.

Significant efforts have been made in selecting suitable materials and forming different layer structures in OLEDs to achieve improved EL performance. Numerous OLEDs with alternative layer structures have been disclosed. For example, in addition to the three layer OLEDs that contain a LEL between the HTL and the ETL (denoted as HTL/LEL/ETL), there are other multilayer OLEDs that contain additional functional layers in the EL unit, such as a hole-injecting layer (HIL), an electron-injecting layer (EIL), an electron-blocking layer (EBL), or a hole-blocking layer (HBL), or the combination thereof. These new layer structures with new materials have indeed resulted in improved device performance.

It has been indicated in prior art that the interface at LEL/ETL is critical to the EL performance of an OLED, especially to that of a blue OLED. This interface influences the luminous efficiency, drive voltage, color gamut, and operational lifetime. Therefore, in order to form an effective interface at the LEL/ETL in an OLED, it is important to select an appropriate material for the ETL. Here, the ETL refers to any layer in direct contact with the LEL on the cathode side, including any layer called EIL, interlayer, HBL, or non-hole-blocking layer in prior art (any layer in direct contact with the LEL in a normal OLED will have the basic function to transport electrons).

The materials for use in the ETL are classified as two types. One is the material that is the same as the dominant host in the LEL, and the other is the material that is different from the dominant host in the LEL. The term “dominant host” means the host material having the highest concentration (by molar ratio) in the LEL. If two host materials have the same concentration in the LEL, one of the two host materials, which has better electron-transporting properties, is most preferably selected as the dominant host. For example, in a conventional green OLED, the dominant host in the LEL is tris(8-hydroxyquinoline)aluminum (Alq), and the same material is also used in the ETL. In a conventional blue OLED, the dominant host for use in the LEL is 2-(1,1-dimethyethyl)-9,10-bis(2-naphthalenyl)anthracene (TBADN), and the same material is also used in the ETL (but called non-hole-blocking layer, as disclosed in U.S. Pat. No. 6,881,502). In this case, there is no interface between the LEL and the ETL. As a result, there is no LEL/ETL interface related problems, such as short operational lifetime or changed color gamut. However, when using this type of ETL in an OLED, the electron injection from the cathode into the LEL cannot be easy due to the lack of intermediate energy step between the Fermi level of the cathode and the LUMO (lowest unoccupied molecular orbital) of the LEL. Moreover, the holes injected from the HTL into the LEL can readily escape from the HOMO (highest occupied molecular orbital) of the LEL due to the lack of hole-blocking effect. Therefore, in this case, the luminous efficiency of the OLED is not high enough and the drive voltage cannot be low enough for real applications.

In the other case where the material used in the ETL is different from the dominant host in the LEL, there is an LEL/ETL interface. For example, in a conventional blue OLED having TBADN as a dominant host in the LEL and having Alq as the material in the ETL, there is a relatively high electron injection barrier between the LUMO of Alq and that of TBADN at the LEL/ETL interface resulting in increased drive voltage. In this case there is no hole-blocking effect because the HOMO of Alq is higher than that of TBADN causing low luminous efficiency. Moreover, the optical bandgap of Alq is smaller than that of the dopant in the LEL introducing some green color emission and causing a change in the color gamut. For another example, in a blue OLED having TBADN as a dominant host in the LEL and 4,7-diphenyl-1,10-phenanthroline (Bphen) as the material in the ETL (or HBL), the luminous efficiency is improved due to the hole-blocking effect, the drive voltage is improved due to better bulk conductivity of Bphen, and there is no change in color gamut. However, because there is no similarity between the molecular structure of TBADN and Bphen, they are unlikely to form an effective interfacial contact. Moreover, the fact that the electron energy difference between the HOMO of Bphen and that of TBADN is about 0.5 eV causes over-accumulation of holes at the LEL/ETL interface and increases the electron-hole recombination probability at the interface. This results in a fast deterioration of the interface, and thus the operational lifetime of the blue OLED having Bphen as ETL (or HBL) is dramatically short.

In order to solve the aforementioned problems at the LEL/ETL interface and to further improve the EL performance of OLEDs, it is necessary to find a way to form an improved LEL/ETL interface in OLEDs.

### SUMMARY OF THE INVENTION

It is therefore an object of the present invention to improve the EL performance of the OLEDs.

The object is achieved by an organic light-emitting device (OLED), comprising:

a) an anode;

b) a cathode;

c) a light-emitting layer disposed between the anode and the cathode, wherein the light-emitting layer includes a dominant host and a dopant; and

d) an electron-transporting layer disposed in direct contact with the light-emitting layer on the cathode side, wherein the electron-transporting layer includes an electron-transporting material having the same chromophore as that of the dominant host in the light-emitting layer, wherein the electron-transporting material constitutes more than 50% by volume of the electron-transporting layer, and wherein the electron-transporting material has a greater reduction potential than that of the dominant host in the light-emitting layer.

The present invention makes use of an ETL with an improved LEL/ETL interface both morphologically and electronically, having a material similar to the dominant host in the LEL but with a reduction potential greater than that of the dominant host in the LEL. It is an advantage of the present invention that the OLED, especially that with a blue color emission, containing this ETL has improved luminous efficiency, improved drive voltage, improved color gamut, and improved operational lifetime.

### BRIEF DESCRIPTION OF THE DRAWINGS

FIG. 1 shows a cross-sectional view of one embodiment of an OLED prepared in accordance with the present invention;

FIG. 2 shows a cross-sectional view of another embodiment of an OLED prepared in accordance with the present invention;

FIG. 3 shows a cross-sectional view of yet another embodiment of an OLED prepared in accordance with the present invention;

FIG. 4 shows a cross-sectional view of yet another embodiment of an OLED prepared in accordance with the present invention;

FIG. 5 shows a cross-sectional view of one embodiment of an OLED having an inverse structure prepared in accordance with the present invention;

FIG. 6 shows a cross-sectional view of another embodiment of an OLED having an inverse structure prepared in accordance with the present invention;

FIG. 7 shows a cross-sectional view of yet another embodiment of an OLED having an inverse structure prepared in accordance with the present invention;

FIG. 8 shows a cross-sectional view of yet another embodiment of an OLED having an inverse structure prepared in accordance with the present invention;

FIG. 9 is a graph showing the normalized luminance vs. operational time of a group of OLEDs tested 70° C. and at 20 mA/cm²; and

FIG. 10 shows the EL spectra of both a prior art OLED and an OLED fabricated according to the present invention.

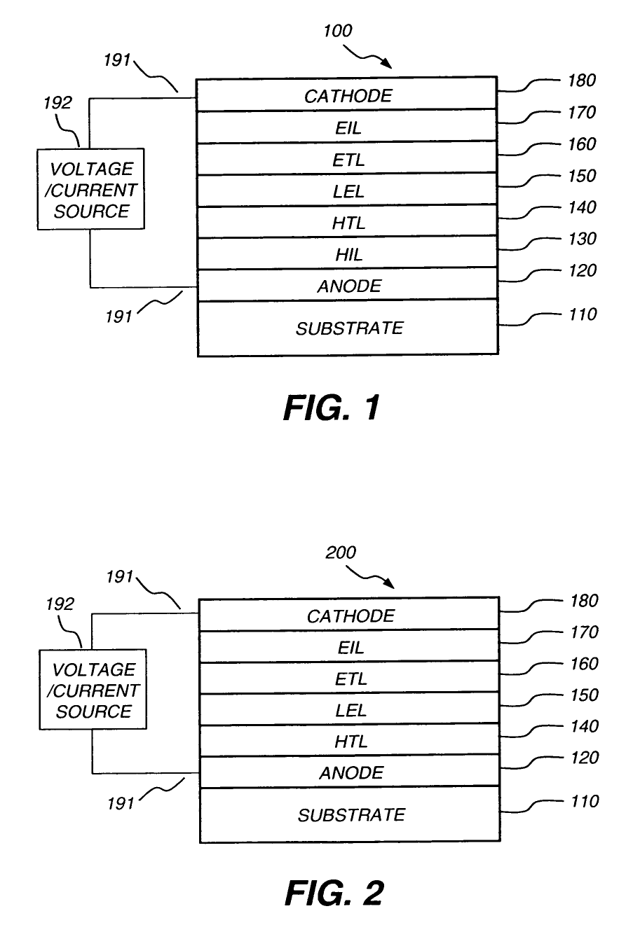

It will be understood that FIGS. 1-8 are not to scale since the individual layers are too thin and the thickness differences of various layers are too great to permit depiction to scale.

### DETAILED DESCRIPTION OF THE INVENTION

As used herein, the term “same chromophore” refers to one or more compounds having the same molecular core structure bearing various substituents. For example, among the anthracene derivatives, both 2-(1,1-dimethyethyl)-9,10-bis(2-naphthalenyl)anthracene (TBADN) and 9,10-bis(2-naphthalenyl)anthracene (AD-N) have the same anthracene chromophore, but TBADN has an additional substituent group; among the tetracene derivatives, both rubrene and 5,6,11,12-tetrakis(2-naphthyl)tetracene have the same tetracene chromophore, but their substituent groups are different.

The present invention is employed in most OLED device configurations. These include very simple structures including a single anode and cathode to more complex devices, such as passive matrix displays including orthogonal arrays of anodes and cathodes to form pixels, and active-matrix displays where each pixel is controlled independently, for example, with thin film transistors (TFTs). There are numerous configurations of the organic layers wherein the present invention is successfully practiced. The essential requirements of an OLED are an anode, a cathode, and an organic light-emitting unit located between the anode and cathode.

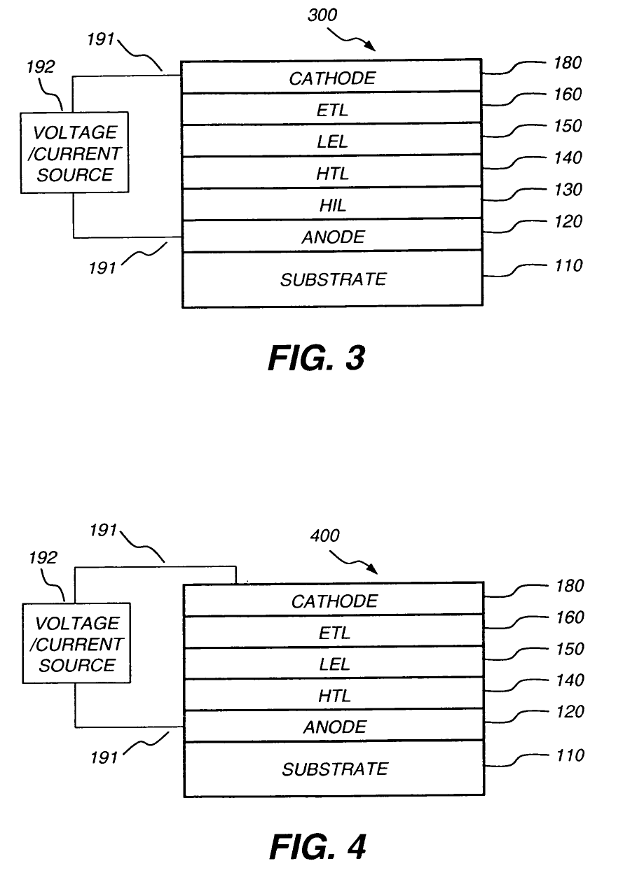

There is shown a cross-sectional view of one embodiment of an OLED in accordance with the present invention in FIG. 1. OLED 100 includes substrate 110, anode 120, HIL 130, HTL 140, LEL 150, ETL 160, EIL 170, and cathode 180. (HIL 130, HTL 140, LEL 150, ETL 160, and EIL 170 form an organic EL unit in between the anode 120 and cathode 180). OLED 100 is externally connected to a voltage/current source 192 through electrical conductors 191. OLED 100 is operated by applying an electric potential produced by the voltage/current source 192 between the pair of contact electrodes, anode 120 and cathode 180. Shown in FIGS. 2, 3, and 4 are OLED 200, OLED 300, and OLED 400, respectively, which are some other embodiments of OLEDs prepared in accordance with the present invention. OLED 200 in FIG. 2 is the same as OLED 100 except that there is no HIL 130 in OLED 200; OLED 300 in FIG. 3 is the same as OLED 100 except that there is no EIL 170 in OLED 300; and OLED 400 in FIG. 4 is the same as OLED 100 except that there is no HIL 130 nor EIL 170 in OLED 400.

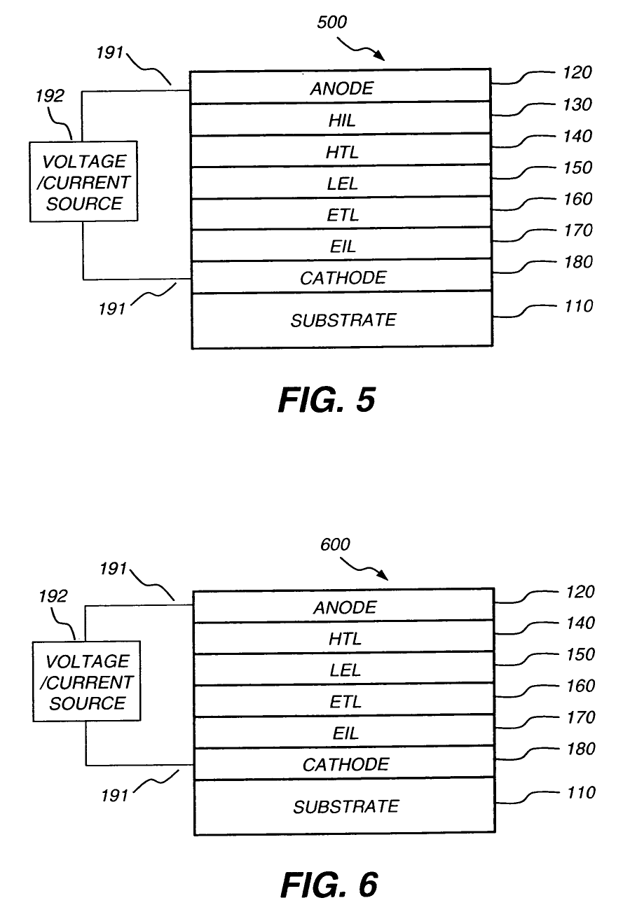

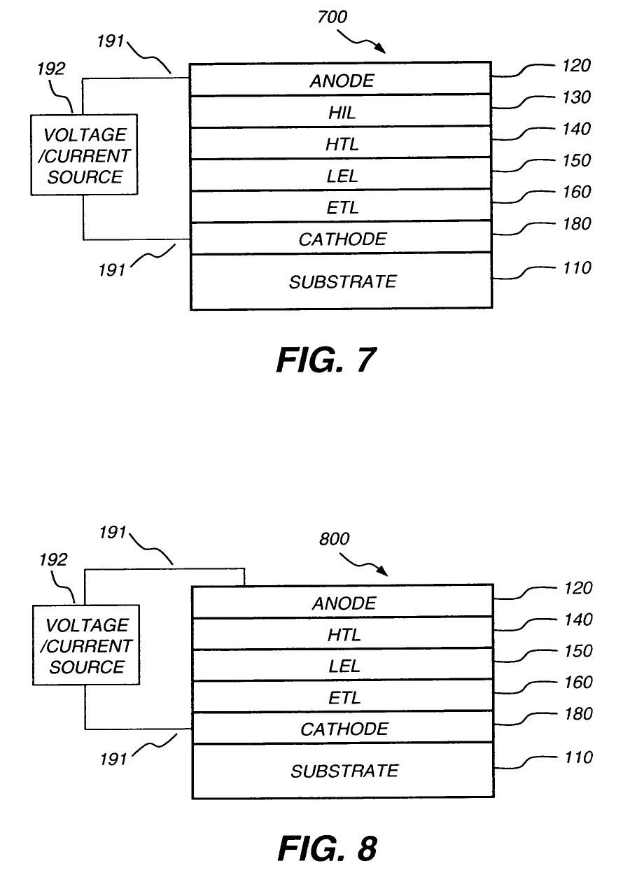

There is shown a cross-sectional view of one embodiment of an OLED having an inverse structure in accordance with the present invention in FIG. 5. OLED 500 includes substrate 110, cathode 180, EIL 170, ETL 160, LEL 150, HTL 140, HIL 130, and anode 120. OLED 500 is also externally connected to a voltage/current source 192 through electrical conductors 191. OLED 500 is operated by applying an electric potential produced by the voltage/current source 192 between the pair of contact electrodes, anode 120 and cathode 180. Shown in FIGS. 6, 7, and 8 are OLED 600, OLED 700, and OLED 800, respectively, which are some other embodiments of OLEDs having an inverse structure prepared in accordance with the present invention. OLED 600 in FIG. 6 is the same as OLED 500 except that there is no HIL 130 in OLED 600; OLED 700 in FIG. 7 is the same as OLED 500 except that there is no EIL 170 in OLED 700; and OLED 800 in FIG. 8 is the same as OLED 500 except that there is no HIL 130 nor EIL 170 in OLED 800.

The following is the description of the device structure, material selection, and fabrication process for the OLED embodiments shown in FIGS. 1-4.

Substrate 110 is an organic solid, an inorganic solid, or include organic and inorganic solids that provides a supporting backplane to hold the OLED. Substrate 110 is rigid or flexible and is processed as separate individual pieces, such as sheets or wafers, or as a continuous roll. Typical substrate materials include glass, plastic, metal, ceramic, semiconductor, metal oxide, semiconductor oxide, or semiconductor nitride, or combinations thereof. Substrate 110 is a homogeneous mixture of materials, a composite of materials, or multiple layers of materials. Substrate 110 can also be a backplane containing TFT circuitry commonly used for preparing OLED display, e.g. an active-matrix low-temperature polysilicon TFT substrate. The substrate 110 can either be light transmissive or opaque, depending on the intended direction of light emission. The light transmissive property is desirable for viewing the EL emission through the substrate. Transparent glass or plastic are commonly employed in such cases. For applications where the EL emission is viewed through the top electrode, the transmissive characteristic of the bottom support is immaterial, and therefore is light transmissive, light absorbing or light reflective. Substrates for use in this case include, but are not limited to, glass, plastic, semiconductor materials, ceramics, and circuit board materials, or any others commonly used in the formation of OLEDs, which are either passive-matrix devices or active-matrix devices.

Anode 120 is formed over substrate 110 in FIGS. 1, 2, 3, and 4. When EL emission is viewed through the substrate 110, the anode should be transparent or substantially transparent to the emission of interest. For applications where EL emission is viewed through the top electrode, the transmissive characteristics of the anode material are immaterial and any conducting or semiconducting material is used, regardless if it is transparent, opaque or reflective. Desired anode materials are deposited by any suitable way such as thermal evaporation, sputtering, chemical vapor deposition, or electrochemical means. Anode materials are patterned using well known photolithographic processes.

The material for use to form anode 120 is selected from inorganic materials, or organic materials, or combination thereof. The anode 120 can contain the element material selected from aluminum, silver, gold, copper, zinc, indium, tin, titanium, zirconium, hafnium, niobium, tantalum, molybdenum, tungsten, manganese, iron, ruthenium, rhodium, iridium, nickel, palladium, platinum, silicon, or germanium, or combinations thereof. The anode 120 can also contain a compound material, such as a conducting or semiconducting compound. The conducting or semiconducting compound is selected from the oxides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof. The conducting or semiconducting compound is selected from the sulfides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof. The conducting or semiconducting compound is selected from the selenides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof. The conducting or semiconducting compound is selected from the tellurides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof. The conducting or semiconducting compound is selected from the nitrides of titanium, zirconium, hafnium, niobium, tantalum, molybdenum, tungsten, manganese, iron, ruthenium, rhodium, iridium, nickel, palladium, platinum, copper, zinc, indium, tin, silicon, or germanium, or combinations thereof. Preferably, the conducting or semiconducting compound is selected from indium-tin oxide, tin oxide, aluminum-doped zinc oxide, indium-doped zinc oxide, magnesium-indium oxide, nickel-tungsten oxide, zinc sulfide, zinc selenide, or gallium nitride, or the combination thereof.

Although it is not always necessary, it is often useful to provide an HIL in the organic EL unit. HIL 130 in the OLEDs can serve to facilitate hole injection from the anode into the HTL, thereby reducing the drive voltage of the OLEDs. Suitable materials for use in HIL 130 include, but are not limited to, porphyrinic compounds as described in U.S. Pat. No. 4,720,432 and some aromatic amines, for example, 4,4′,4″-tris[(3-ethylphenyl)phenylamino]triphenylamine (m-TDATA). Alternative hole-injecting materials reportedly useful in organic EL devices are described in EP 0 891 121 A1 and EP 1 029 909 A1. Aromatic tertiary amines discussed below can also be useful as hole-injecting materials. Other useful hole-injecting materials such as dipyrazino[2,3-f:2′,3′-h]quinoxalinehexacarbonitrile are described in U.S. Patent Application Publication 2004/0113547 A1 and U.S. Pat. No. 6,720,573. In addition, a p-type doped organic layer is also useful for the HIL as described in U.S. Pat. No. 6,423,429. The term “p-type doped organic layer” means that this layer has semiconducting properties after doping, and the electrical current through this layer is substantially carried by the holes. The conductivity is provided by the formation of a charge-transfer complex as a result of hole transfer from the dopant to the host material. The thickness of the HIL 130 is in the range of from 0.1 nm to 200 nm, preferably, in the range of from 0.5 nm to 150 nm.

The HTL 140 contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine is an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals or at least one active hydrogen-containing group are disclosed by Brantley, et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. Such compounds include those represented by structural Formula A 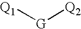
wherein:

Q₁ and Q₂ are independently selected aromatic tertiary amine moieties; and

G is a linking group such as an arylene, cycloalkylene, or alkylene group of a carbon to carbon bond.

In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula B 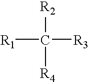
wherein:

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural Formula C 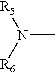
wherein R₅ and R₆ are independently selected aryl groups.
In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula C, linked through an arylene group. Useful tetraaryldiamines include those represented by Formula D 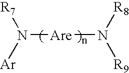
wherein:

each Are is an independently selected arylene group, such as a phenylene or anthracene moiety;

n is an integer of from 1 to 4; and

Ar, R₇, R₈, and R₉ are independently selected aryl groups. In a typical embodiment, at least one of Ar, R₇, R₈, and R₉ is a polycyclic fused ring structure, e.g., a naphthalene.

The various alkyl, alkylene, aryl, and arylene moieties of the foregoing structural Formulae A, B, C, and D can each in turn be substituted. Typical substituents include alkyl groups, alkoxy groups, aryl groups, aryloxy groups, and halogen such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms, e.g. cyclopentyl, cyclohexyl, and cycloheptyl ring structures. The aryl and arylene moieties are typically phenyl and phenylene moieties.

The HTL is formed of a single or a mixture of aromatic tertiary amine compounds. Specifically, one can employ a triarylamine, such as a triarylamine satisfying the Formula B, in combination with a tetraaryldiamine, such as indicated by Formula D. When a triarylamine is employed in combination with a tetraaryldiamine, the latter is positioned as a layer interposed between the triarylamine and the electron injecting and transporting layer. Aromatic tertiary amines are useful as hole injection materials also. Illustrative of useful aromatic tertiary amines are the following:

1,1-bis(4-di-p-tolylaminophenyl)cyclohexane;

1,1-bis(4-di-p-tolylaminophenyl)-4-phenylcyclohexane;

1,5-bis[N-(1-naphthyl)-N-phenylamino]naphthalene;

2,6-bis(di-p-tolylamino)naphthalene;

2,6-bis[di-(1-naphthyl)amino]naphthalene;

2,6-bis[N-(1-naphthyl)-N-(2-naphthyl)amino]naphthalene;

2,6-bis[N,N-di(2-naphthyl)amine]fluorene;

4-(di-p-tolylamino)-4′-[4(di-p-tolylamino)-styryl]stilbene;

4,4′-bis(diphenylamino)quadriphenyl;

4,4″-bis[N-(1-anthryl)-N-phenylamino]-p-terphenyl;

4,4′-bis[N-(1-coronenyl)-N-phenylamino]biphenyl;

4,4′-bis[N-(1-naphthyl)-N-phenylamino]biphenyl (NPB);

4,4′-bis[N-(1-naphthyl)-N-(2-naphthyl)amino]biphenyl (TNB);

4,4″-bis[N-(1-naphthyl)-N-phenylamino]p-terphenyl;

4,4′-bis[N-(2-naphthacenyl)-N-phenylamino]biphenyl;

4,4′-bis[N-(2-naphthyl)-N-phenylamino]biphenyl;

4,4′-bis[N-(2-perylenyl)-N-phenylamino]biphenyl;

4,4′-bis[N-(2-phenanthryl)-N-phenylamino]biphenyl;

4,4′-bis[N-(2-pyrenyl)-N-phenyl amino]biphenyl;

4,4′-bis[N-(3-acenaphthenyl)-N-phenylamino]biphenyl;

4,4′-bis[N-(3-methylphenyl)-N-phenylamino]biphenyl (TPD);

4,4′-bis[N-(8-fluoranthenyl)-N-phenylamino]biphenyl;

4,4′-bis[N-(9-anthryl)-N-phenylamino]biphenyl;

4,4′-bis {N-phenyl-N-[4-(1-naphthyl)-phenyl]amino}biphenyl;

4,4′-bis[N-phenyl-N-(2-pyrenyl)amino]biphenyl;

4,4′,4″-tris[(3-methylphenyl)phenylamino]triphenylamine (m-TDATA);

Bis(4-dimethylamino-2-methylphenyl)-phenylmethane;

N-phenylcarbazole;

N,N′-bis[4-([1,1′-biphenyl]-4-ylphenylamino)phenyl]-N,N′-di-1-napbthalenyl-[1,1′-biphenyl]-4,4′-diamine;

N,N′-bis[4-(di-1-naphtbalenylamino)phenyl]-N,N′-di-1-naphthalenyl-[1,1′-biphenyl]-4,4′-diamine;

N,N′-bis[4-[(3-methylphenyl)phenylamino]phenyl]-N,N′-diphenyl-[1,1′-bipbenyl]-4,4′-diamine;

N,N-bis[4-(diphenylamino)phenyl]-N′,N′-dipheny-[1,1′-biphenyl]-4,4′-diamine;

N,N′-di-1-naphthalenyl-N,N′-bis[4-(1-naphthalenylphenylamino)phenyl]-[1,1′-biphenyl]-4,4′-diamine;

N,N′-di-1-naphthalenyl-N,N′-bis[4-(2-naphthalenylphenylamino)phenyl]-[1,1′-biphenyl]-4,4′-diamine;

N,N,N-tri(p-tolyl)amine;

N,N,N′,N′-tetra-p-tolyl-4-4′-diaminobiphenyl;

N,N,N′,N′-tetraphenyl-4,4′-diaminobiphenyl;

N,N,N′,N′-tetra-1-naphthyl-4,4′-diaminobiphenyl;

N,N,N′,N′-tetra-2-naphthyl-4,4′-diaminobiphenyl; and

N,N,N′,N′-tetra(2-naphthyl)-4,4″-diamino-p-terphenyl.

Another class of useful hole-transporting materials includes polycyclic aromatic compounds as described in EP 1 009 041. Tertiary aromatic amines with more than two amine groups can be used including oligomeric materials. In addition, polymeric hole-transporting materials are used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

The thickness of HTL 140 is in the range of from 5 nm to 200 nm, preferably, in the range of from 10 nm to 150 nm.

Typically the LEL 150 includes a luminescent fluorescent or phosphorescent material where electroluminescence is produced as a result of electron-hole pair recombination in this layer. The LEL includes a single material, but more commonly contains at least one host material doped with at least one emitting material. The host material in the LEL is an electron-transporting, hole-transporting, or another material or combination of materials that support hole-electron recombination. The emitting material is often referred to as a dopant. The dopant is typically chosen from highly fluorescent dyes and phosphorescent compounds, e.g., transition metal complexes as described in WO 98/55561, WO 00/18851, WO 00/57676, and WO 00/70655. Dopant materials are typically incorporated at 0.01 to 20% level by volume of the host material.

Host and dopants known to be of use include, but are not limited to, those disclosed in U.S. Pat. Nos. 4,768,292, 5,141,671, 5,150,006, 5,151,629, 5,405,709, 5,484,922, 5,593,788, 5,645,948, 5,683,823, 5,755,999, 5,928,802, 5,935,720, 5,935,721, 6,020,078, 6,475,648, 6,534,199, 6,661,023, U.S. Patent Application Publications 2002/0127427 A1, 2003/0198829 A1, 2003/0203234 A1, 2003/0224202 A1, and 2004/0001969 A1.

One class of host materials includes metal complexes of 8-hydroxyquinoline (oxine) and similar derivatives capable of supporting electroluminescence. Exemplary of contemplated oxinoid compounds are those satisfying structural Formula E 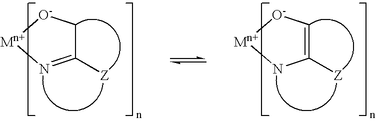
wherein:

M represents a metal;

n is an integer of from 1 to 4; and

Z independently in each occurrence represents the atoms completing a nucleus having at least two fused aromatic rings.

Another class of useful host materials includes derivatives of anthracene, such as those described in U.S. Pat. Nos. 5,935,721, 5,972,247, 6,465,115, 6,534,199, 6,713,192, U.S. Patent Application Publications 2002/0048687 A1, 200/30072966 A1, and WO 2004018587. Common examples include 9,10-bis(2-naphthalenyl)anthracene (AD-N), 2-(1,1-dimethyethyl)-9,10-bis(2-naphthalenyl)anthracene (TBADN). Other examples include different derivatives of AD-N, such as those represented by Formula F 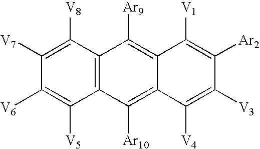
wherein:

Ar₂, Ar₉, and Ar₁₀ independently represent an aryl group;

v₁, v₃, v₄, v₅, v₆, v₇, and v₈ independently represent hydrogen or a substituent;

and Formula G 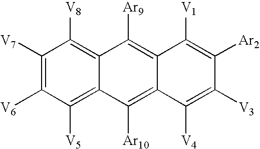
wherein:

Ar₉, and Ar₁₀ independently represent an aryl group;

v₁, v₂, v₃, v₄, v₅, v₆, v₇, and v₈ independently represent hydrogen or a substituent.

Yet another class of host materials includes rubrene and other tetracene derivatives. Some examples are represented by Formula H 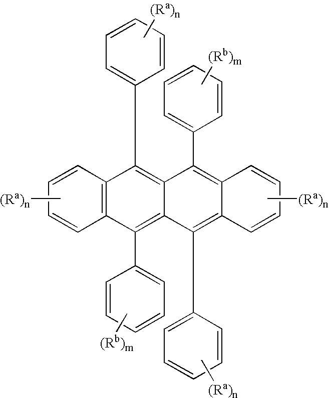
wherein:

R^{a} and R^{b} are substituent groups;

n is selected from 0-4; and

m is selected from 0-5.

Other useful classes of host materials include distyrylarylene derivatives as described in U.S. Pat. No. 5,121,029, and benzazole derivatives, for example, 2,2′,2″-(1,3,5-phenylene)tris[1-phenyl-1H-benzimidazole].

Suitable host materials for phosphorescent dopants are selected so that the triplet exciton is transferred efficiently from the host material to the phosphorescent material. For this transfer to occur, it is a highly desirable condition that the excited state energy of the phosphorescent material be lower than the difference in energy between the lowest triplet state and the ground state of the host. However, the bandgap of the host should not be chosen so large as to cause an unacceptable increase in the drive voltage of the OLEDs. Suitable host materials are described in WO 00/70655 A2, WO 01/39234 A2, WO 01/93642 A1, WO 02/074015 A2, WO 02/15645 A1, and U.S. Patent Application Publication 2002/0117662 A1. Suitable hosts include certain aryl amines, triazoles, indoles and carbazole compounds. Examples of desirable hosts are 4,4′-N,N′-dicarbazole-biphenyl (CBP), 2,2′-dimethyl-4,4′-N,N′-dicarbazole-biphenyl, m-(N,N′-dicarbazole)benzene, and poly(N-vinylcarbazole), including their derivatives.

Desirable host materials are capable of forming a continuous film. The LEL can contain more than one host material in order to improve the device's film morphology, electrical properties, light emission efficiency, and operational lifetime. Mixtures of electron-transporting and hole-transporting materials are known as useful hosts. In addition, mixtures of the above listed host materials with hole-transporting or electron-transporting materials can make suitable hosts.

For efficient energy transfer from the host to the dopant material, a necessary condition is that the bandgap of the dopant is smaller than that of the host material. For phosphorescent emitters (including materials that emit from a triplet excited state, i.e. so-called “triplet emitters”) it is also important that the triplet energy level of the host be high enough to enable energy transfer from host to dopant material.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives, bis(azinyl)amine boron compounds, bis(azinyl)methane boron compounds, derivatives of distryrylbenzene and distyrylbiphenyl, and carbostyryl compounds. Among derivatives of distyrylbenzene, particularly useful are those substituted with diarylamino groups, also known as distyrylamines. Illustrative examples of useful materials include, but are not limited to, the following:

| | |
|---|---|
| | L1 |
| 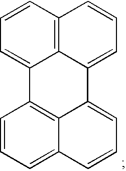 | |
| | L2 |
| 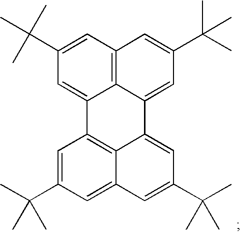 | |
| | L3 |
| 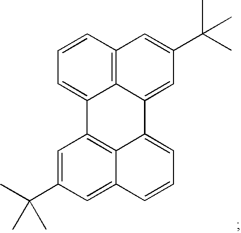 | |
| | L4 |
| 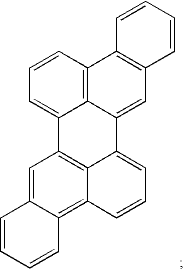 | |
| | L5 |
| 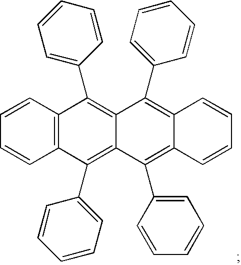 | |
| | L6 |
| 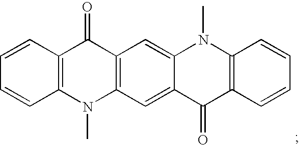 | |
| | L7 |
| 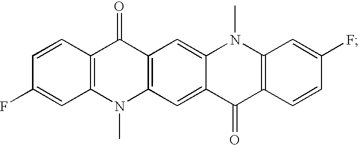 | |
| | L8 |
| 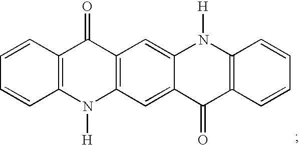 | |
| 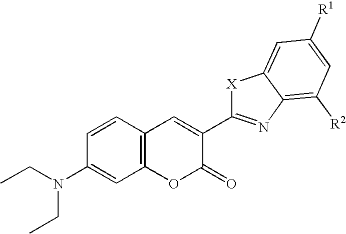 | |

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl; |

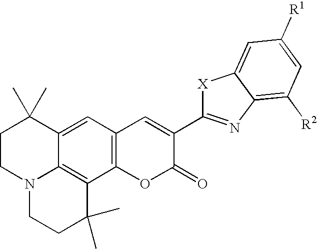

| | X | R1 | R2 |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl; |

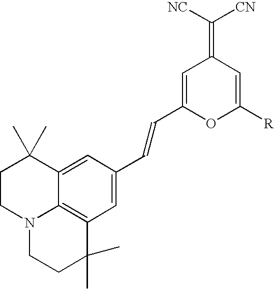

| | R |
|---|---|
| L37 | phenyl |
| L38 | methyl |
| L39 | t-butyl |
| L40 | mesityl; |

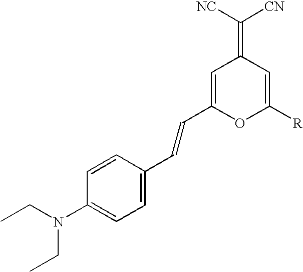

| | R |
|---|---|
| L41 | phenyl |
| L42 | methyl |
| L43 | t-butyl |
| L44 | mesityl; |

| | |
|---|---|
| | L45 |
| 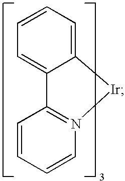 | |
| | L46 |
| 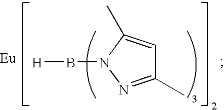 | |
| | L47 |
| 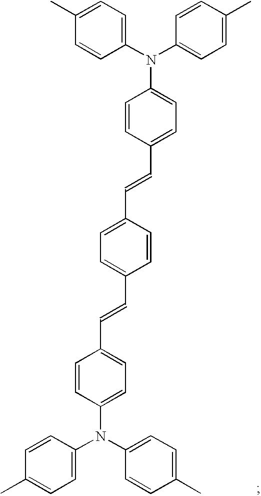 | |
| | L48 |
| 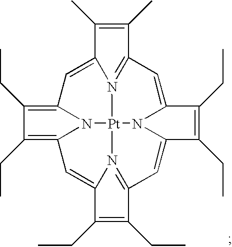 | |
| | L49 |
| 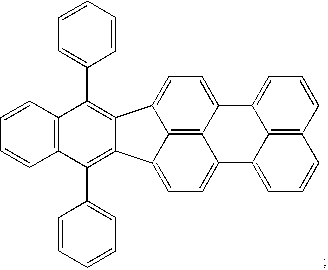 | |
| | L50 |
| 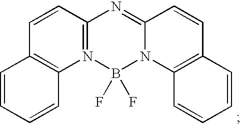 | |
| | L51 |
| 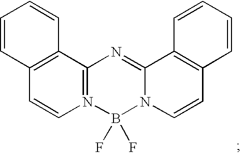 | |
| | L52 |
| 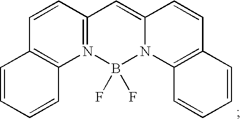 | |
| | L53 |
| 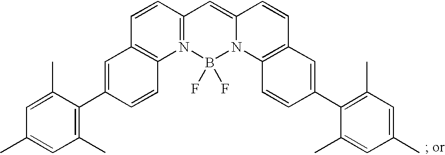 | |
| | L54 |
| 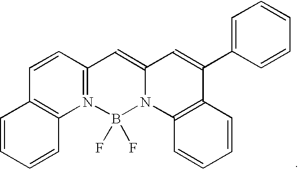 | |

Examples of useful phosphorescent dopants that are used in light-emitting layers of this invention include, but are not limited to, those described in WO 00/57676, WO 00/70655, WO 01/41512 A1, WO 02/15645 A1, WO 02/071813 A1, WO 01/93642 A1, WO 01/39234 A2,WO 02/074015 A2, U.S. Pat. Nos. 6,458,475, 6,573,651, 6,451,455, 6,413,656, 6,515,298, 6,451,415, 6,097,147, U.S. Patent Application Publications 2003/0017361 A1, 2002/0197511 A1, 2003/0072964 A1, 2003/0068528 A1, 2003/0124381 A1, 2003/0059646 A1, 2003/0054198 A1, 2002/0100906 A1, 2003/0068526 A1, 2003/0068535 A1, 2003/0141809 A1, 2003/0040627 A1, 2002/0121638 A1, EP 1 239 526 A2, EP 1 238 981 A2, and EP 1 244 155 A2. Preferably, the useful phosphorescent dopants include transition metal complexes, such as iridium and platinum complexes.

The host and dopant are small nonpolymeric molecules or polymeric materials including polyfluorenes and polyvinylarylenes (e.g., poly(p-phenylenevinylene), PPV). In the case of polymers, a small molecule dopant is molecularly dispersed into a polymeric host, or the dopant is added by copolymerizing a minor constituent into a host polymer.

In some cases it is useful for one or more of the LELs within an EL unit to emit broadband light, for example white light. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. Nos. 5,683,823, 5,503,910, 5,405,709, 5,283,182, 6,627,333, 6,696,177, 6,720,092, U.S. Patent Application Publications 2002/0186214 A1, 2002/0025419 A1, and 2004/0009367 A1. In some of these systems, the host for one light-emitting layer is a hole-transporting material. For example, it is known in the art that dopants are added to the HTL 140, thereby enabling HTL 140 to serve as a host. The thickness of each LEL is in the range of from 5 nm to 50 nm, preferably, in the range of from 10 nm to 40 nm.

ETL 160 is a unique layer of the present invention such that the material in ETL 160 is sleceted to have the same chromophore as that of the dominant host in LEL 150.

If the dominant host in LEL 150 is a metal chelated oxinoid compound, the material used in ETL 160 is seleted from different metal chelated oxinoid compounds including chelates of oxine itself (also commonly referred to as 8-quinolinol or 8-hydroxyquinoline). Exemplary of contemplated oxinoid compounds are those satisfying structural Formula E 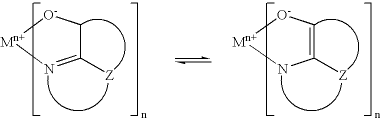
wherein:

M represents a metal;

n is an integer of from 1 to 4; and

Z independently in each occurrence represents the atoms completing a nucleus having at least two fused aromatic rings.

Illustrative of useful chelated oxinoid compounds for use in ETL 160 are the following:

CO-1: Aluminum trisoxine [alias, tris(8-quinolinolato)aluminum(III)];

CO-2: Magnesium bisoxine [alias, bis(8-quinolinolato)magnesium(II)];

CO-3: Bis[benzo{f}-8-quinolinolato]zinc (II);

CO-4: Bis(2-methyl-8-quinolinolato)aluminum(III)-μ-oxo-bis(2-methyl-8-quinolinolato)aluminum(III);

CO-5: Indium trisoxine [alias, tris(8-quinolinolato)indium];

CO-6: Aluminum tris(5-methyloxine) [alias, tris(5-methyl-8-quinolinolato)aluminum(III)];

CO-7: Lithium oxine [alias, (8-quinolinolato)lithium(I)];

CO-8: Gallium oxine [alias, tris(8-quinolinolato)gallium(III)]; and
CO-9: Zirconium oxine [alias, tetra(8-quinolinolato)zirconium(IV)].

If the dominant host in LEL 150 is an anthracene derivative, the material used in ETL 160 is seleted from different anthracene derivatives. The examples include derivatives of A-DN, and derivatives of (9-naphthyl-10-phenyl)anthracene, such as those represented by Formula F 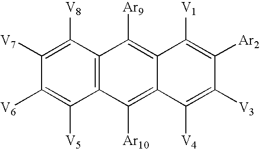
wherein:

Ar₂, Ar₉, and Ar₁₀ independently represent an aryl group;

v₁, v₃, v₄, v₅, v₆, v₇, and v₈ independently represent hydrogen or a substituent; and

Formula G 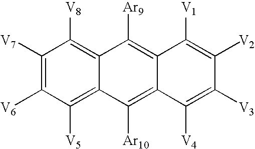
wherein:

Ar₉, and Ar₁₀ independently represent an aryl group; and

v₁, v₂, v₃, v₄, v₅, v₆, v₇, and v₈ independently represent hydrogen or a substituent.

The term “substituent” means any group or atom other than hydrogen. Unless otherwise provided, when a group (including a compound or complex) containing a substitutable hydrogen is referred to, it is also intended to encompass not only the unsubstituted form, but also form further substituted with any substituent group or groups as herein or hereafter mentioned, so long as the substituent does not destroy properties necessary for utility. Suitably, a substituent group can be halogen or can be bonded to the remainder of the molecule by an atom of carbon, silicon, oxygen, nitrogen, phosphorous, sulfur, selenium, or boron. The substituent includes, for example, halogen, such as chloro, bromo or fluoro; nitro; hydroxyl; cyano; carboxyl; or groups which can be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolylcarbonylamino, N-methylureido, N,N-dimethylureido, N-methyl -N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentyl-phenyl)-N′-ethylureido and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropylsulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentyl-phenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which can be substituted and which contain a 3 to 7 membered heterocyclic ring composed of carbon atoms and at least one hetero atom selected from the group including oxygen, nitrogen, sulfur, phosphorous, or boron such as 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents can themselves be further substituted one or more times with the described substituent groups. The particular substituents used can be selected by those skilled in the art to attain the desired desirable properties for a specific application and can include, for example, electron-withdrawing groups, electron-donating groups, and steric groups. When a molecule can have two or more substituents, the substituents can be joined together to form a ring such as a fused ring unless otherwise provided. Generally, the above groups and substituents thereof can include those having up to 48 carbon atoms, typically 1 to 36 carbon atoms and typically less than 24 carbon atoms, but greater numbers are possible depending on the particular substituents selected.

More specific examples of this class of ETL materials are represented by: 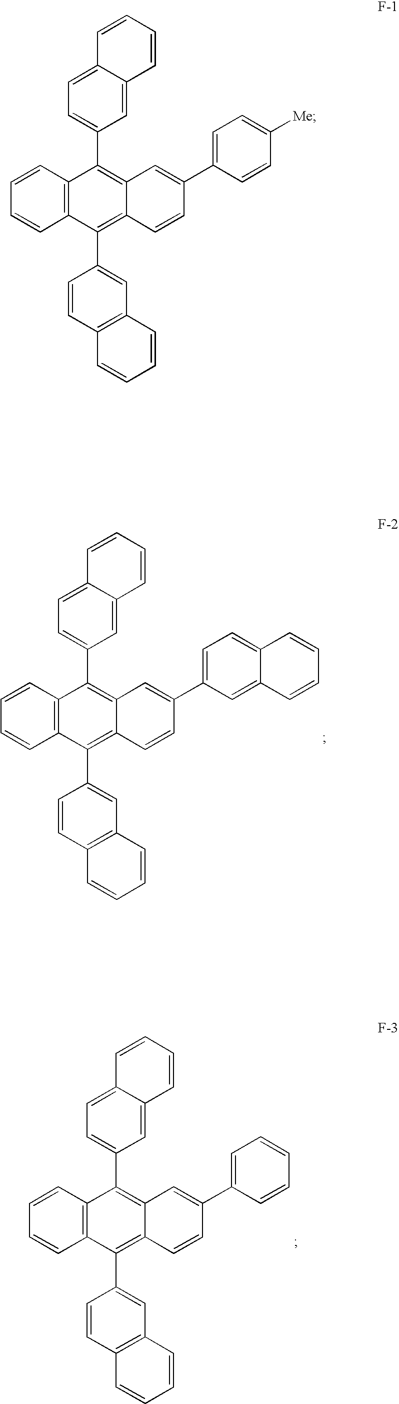 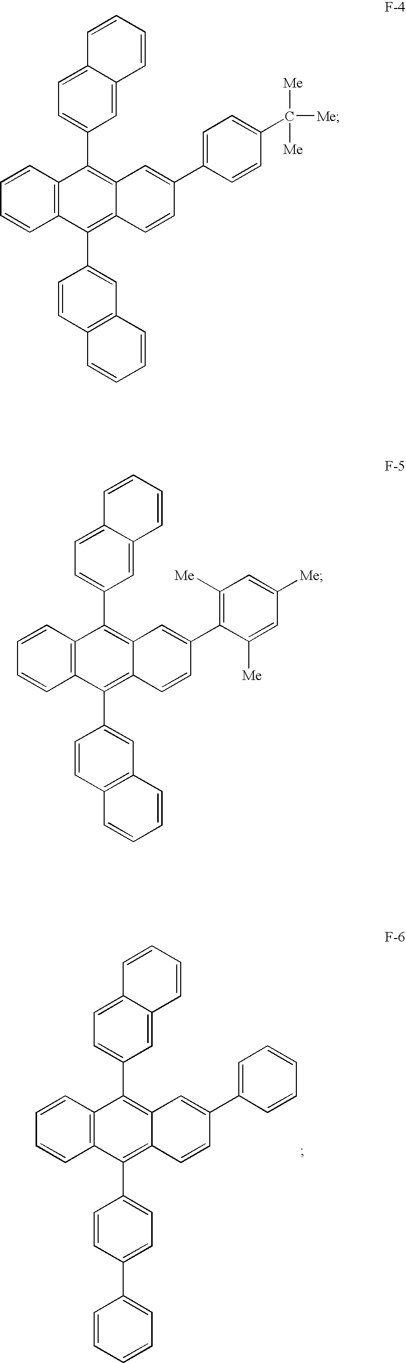 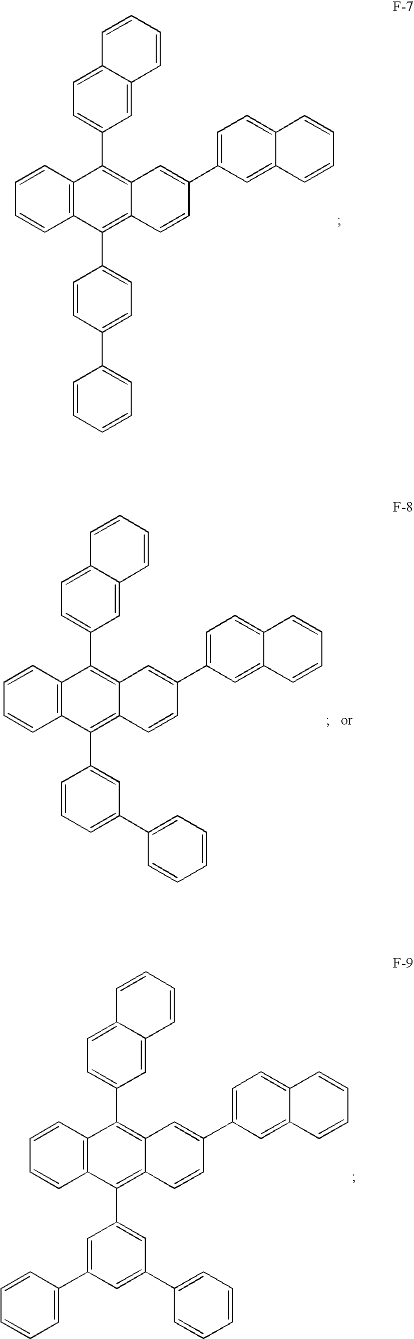
and represented by:

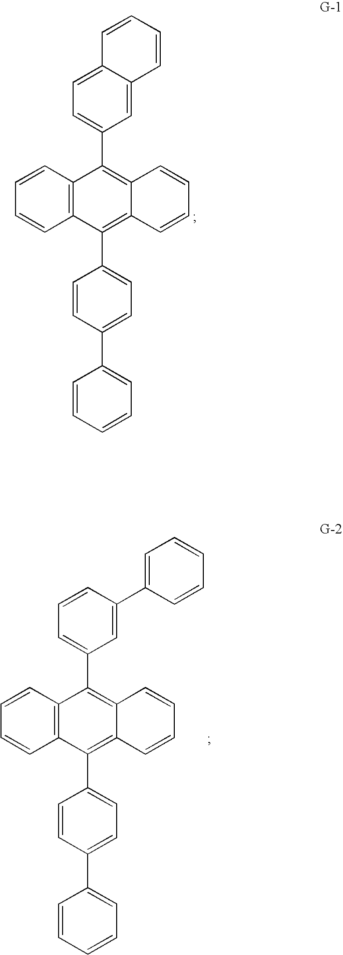

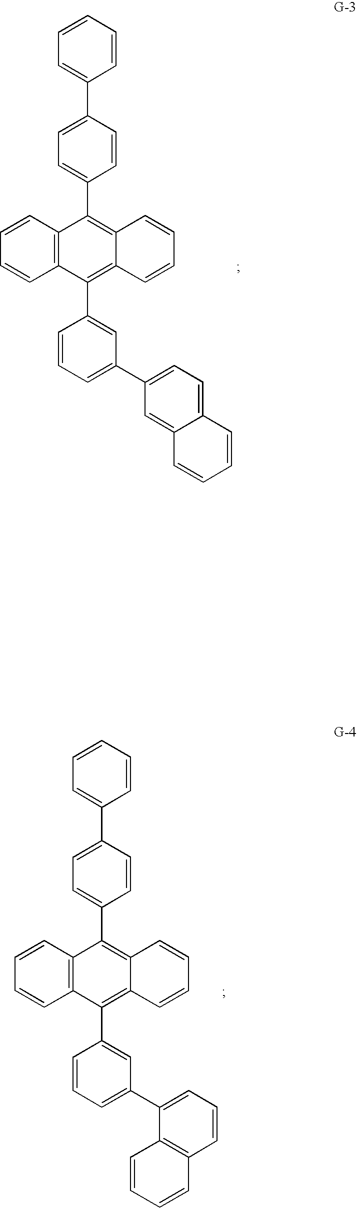

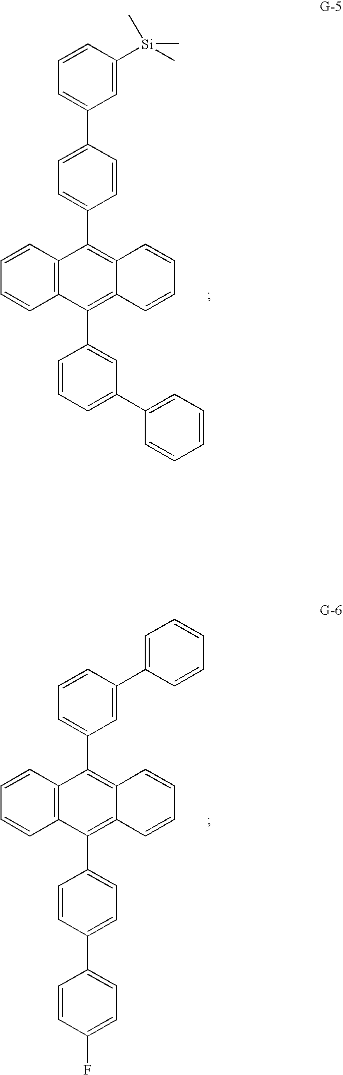

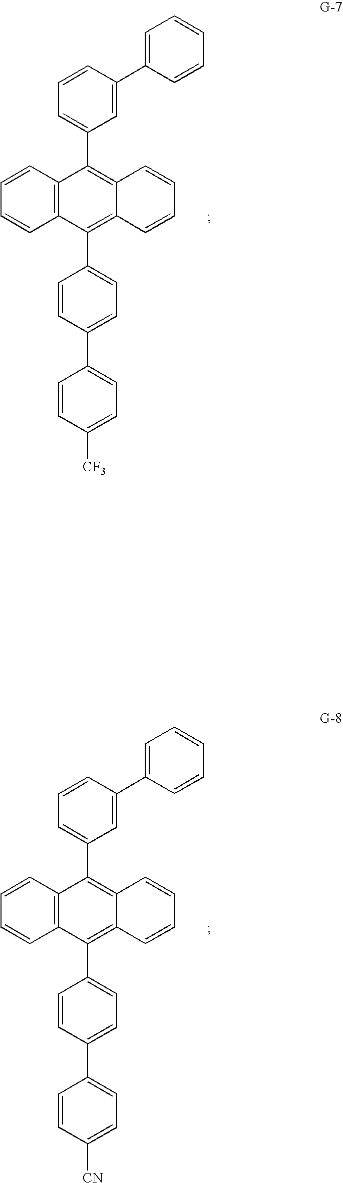

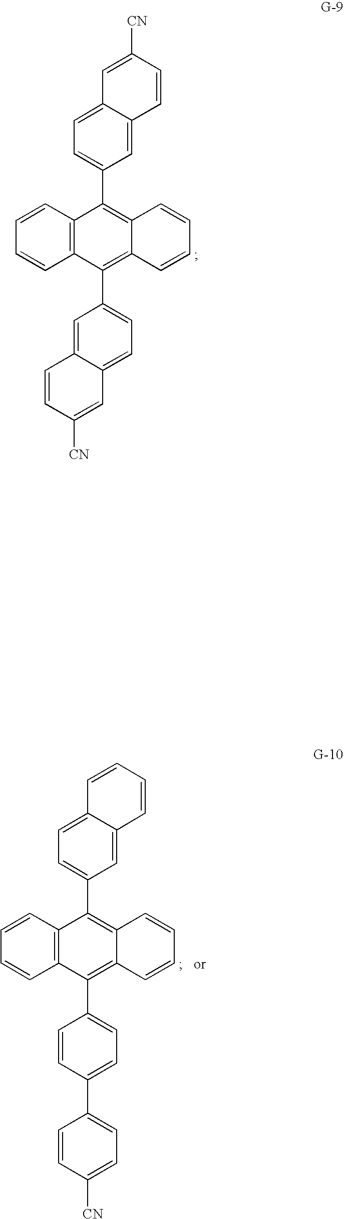

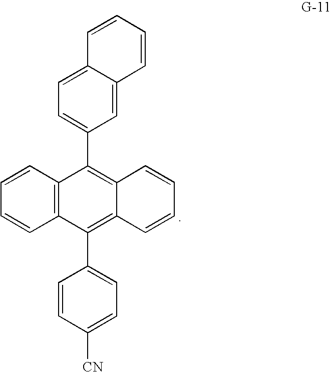

If the dominant host in LEL 150 is a tetracene derivative, the material used in ETL 160 is seleted from different tetracene derivatives. Some examples are represented by Formula H 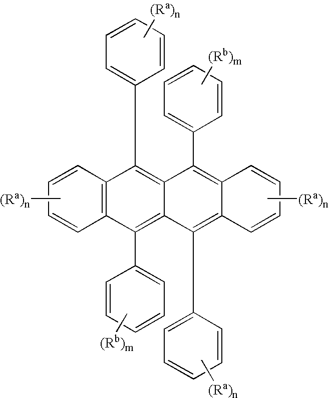
wherein:

R^{a} and R^{b} are substituent groups;

n is selected from 0-4; and

m is selected from 0-5.

More specific examples are represented by:

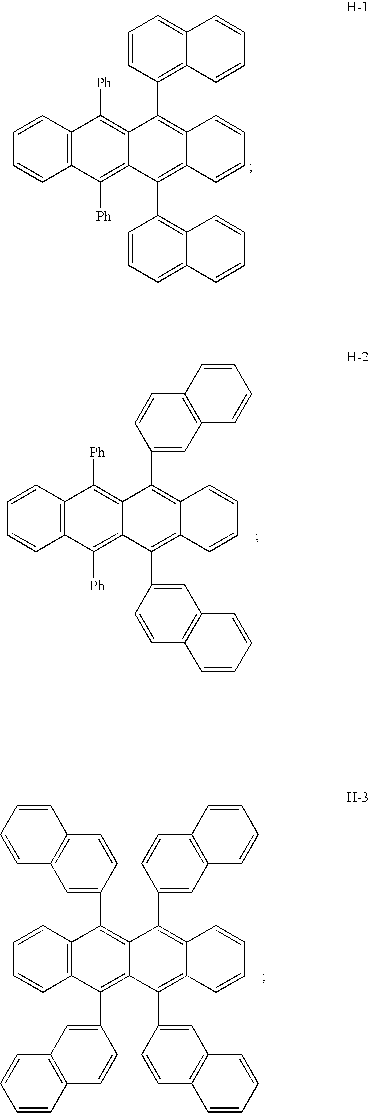

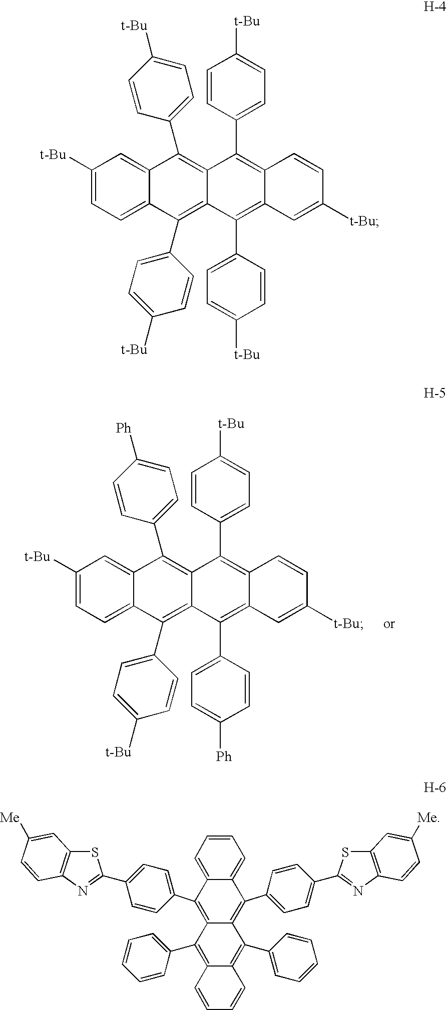

If the dominant host in LEL 150 is other material, such as distyrylarylene derivatives as described in U.S. Pat. No. 5,121,029, and benzazole derivatives, the material used in ETL 160 is seleted from different distyrylarylene derivatives and different benzazole derivatives accordingly.

The high similarity between two materials used in each of the ajacent layers can avoid a dramtical change at the contact interface resulting in an improved interfacial contact. Thus, improved operational stability of the OLEDs is expected.

In the present invention, the material for use in ETL 160 is selected not only to have the same chromophore as that of the dominant host in LEL 150 as described above, but also to have a greater reduction potential than that of the dominant host in LEL 150. Having greater reduction potential than that of the dominant host in LEL 150 also means having lower LUMO postion (relative to the Vacuum Energy Level) than that of the dominant host in LEL 150. In this configuration, it produces an intermediate energy level between the LUMO of ETL 160 and the Fermi level of cathode 180. In other words, the electron injection barrier between cathode 180 and LEL 150 is effectively reduced by dividing the one barrier into two smaller barriers when inserting the ETL 160. As a result, electrons are more readily injected from cathode 180 to ETL 160, and then from ETL 160 to LEL 150. Preferably, the difference between the LUMO of ETL 160 and that of LEL 150 is less than 0.3 eV, or the differencen between the reduction potential of ETL 160 and that of LEL 150 is less than 0.3 V.

In order to have improved luminous efficiency, it is desirable but not necessary, to produce a small barrier to hinder holes from escaping into ETL 160. Therefore, the HOMO (or ionization potential) of the material in ETL 160 is lower than that of the host material in LEL 150 preferably by a difference within 0.3 eV. In other words, the oxidation potential of the material in ETL 160 is greater than that of the host material in LEL 150 preferably by a difference within 0.3 V. If the difference of the oxidation potentials is greater than 0.3 V, it will have a negative effect on operational lifetime similar to what the HBL does.

The term “reduction potential”, expressed in volts and abbreviated E^{red}, measures the affinity of a substance for an electron: the larger (more positive) the value, the greater the affinity. The reduction potential of a substance is conveniently obtained by cyclic voltammetry (CV) and it is measured vs. SCE. The measurement of the reduction potential of a substance is as following: An electrochemical analyzer (for instance, a CHI660 electrochemical analyzer, made by CH Instruments, Inc., Austin, Tex.) is employed to carry out the electrochemical measurements. Both CV and Osteryoung square-wave voltammetry (SWV) are used to characterize the redox properties of the substance. A glassy carbon (GC) disk electrode (A=0.071 cm²) is used as working electrode. The GC electrode is polished with 0.05 μm alumina slurry, followed by sonication cleaning in deionized water twice and rinsed with acetone between the two water cleanings. The electrode is finally cleaned and activated by electrochemical treatment prior to use. A platinum wire is used as the counter electrode and the SCE is used as a quasi-reference electrode to complete a standard 3-electrode electrochemical cell. A mixture of acetonitrile and toluene (1:1 MeCN/toluene) or methylene chloride (MeCl₂) is used as organic solvent systems. All solvents used are ultra low water grade (<10 ppm water). The supporting electrolyte, tetrabutylammonium tetrafluoroborate (TBAF), is recrystallized twice in isopropanol and dried under vacuum for three days. Ferrocene (Fc) is used as an internal standard (E^{red}_{Fc}=0.50 V vs. SCE in 1:1 MeCN/toluene, E^{red}_{Fc}=0.55 V vs. SCE in MeCl₂, 0.1 M TBAF, both values referring to the reduction of the ferrocenium radical anion). The testing solution is purged with high purity nitrogen gas for approximately 15 minutes to remove oxygen and a nitrogen blanket is kept on the top of the solution during the course of the experiments. All measurements are performed at an ambient temperature of 25±1° C. If the compound of interest has insufficient solubility, other solvents are selected and used by those skilled in the art. Alternatively, if a suitable solvent system cannot be identified, the electron-accepting material is deposited onto the electrode and the reduction potential of the modified electrode is measured.

Similarly, the term “oxidation potential”, expressed in volts and abbreviated E^{ox}, measures the ability to lose electron from a substance: the larger the value, the more difficult to lose electron. The oxidation potential of a substance can also be conveniently obtained by a CV as discussed above.

Having the same chromophore between the materials in ETL 160 and the host material in LEL 150 can also imply that the energy bandgaps of the two materials are similar. The energy bandgap is defined as the energy difference between the reduction potential and the oxdiation potential of a material, multiplied by one electron unit, or between the LUMO and the HOMO of the material. For example, Molecule F-3 as the material in ETL 160 has the same anthracene chromophore as TBADN, the dominant host in LEL 150 in an OLED. The energy bandgap of Molecule F-3 is about 3.06 eV, and that of TBADN is about 3.16 eV, which are similar to each other. Since the energy bandgaps of ETL 160 and LEL 150 are similar, it will be likely having a similar color emission from the ETL 160, if there is any exciton diffussion into this layer.

In order to further improve the electron-transporting and injecting properties, ETL 160 is formed using two or more than two materials, wherein one is similar to the dominant host in LEL 150 and constitutes more than 50% by volume of this ETL (ETL 160), and the others are other type of materials, as long as the EL performance of the OLED is improved. ETL 160 can also include a dopant having a work function lower than 4.0 eV. The dopant in ETL 160 includes an alkali metal, alkali metal compound, alkaline earth metal, or alkaline earth metal compound. Preferably, the dopant in ETL 160 includes Li, Na, K, Rb, Cs, Mg, Ca, Sr, Ba, La, Ce, Nd, Sm, Eu, Th, Dy, or Yb. The concentration of the dopant in ETL 160 is in the range of from 0.01% to 20% by volume of the ETL. And the thickness of ETL 160 is in the range of from 1 nm to 70 nm, preferably, from 2 nm to 20 nm.

EIL 170 is an n-type doped layer containing at least one electron-transporting material as a host material and at least one n-type dopant The dopant is capable of reducing the organic host material by charge transfer. The term “n-type doped layer” means that this layer has semiconducting properties after doping, and the electrical current through this layer is substantially carried by the electrons. The host material in EIL 170 is an electron-transporting material capable of supporting electron injection and electron transport.

The host material in EIL 170 is selected from oxinoid compounds represented by Formula E 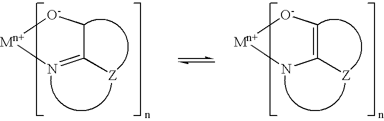
wherein:

M represents a metal;

n is an integer of from 1 to 4; and

Z independently in each occurrence represents the atoms completing a nucleus having at least two fused aromatic rings.

Illustrative of useful chelated oxinoid compounds for use in EIL 170 are CO-1-CO-9 as mentioned in ETL 160.

The host material in EIL 170 is selected from the compounds represented by Formula H 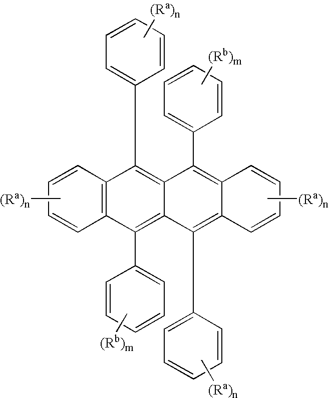
wherein:

R^{a} and R^{b} are substituent groups;

n is selected from 0-4; and

m is selected from 0-5.

The host material in EIL 170 is selected from the compounds represented by Formula I 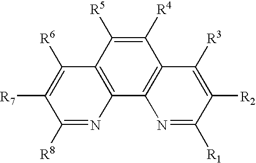
wherein R₁—R₈ are independently hydrogen, alkyl, aryl or substituted aryl, and at least one of R₁—R₈ is aryl or substituted aryl. Suitable the electron-transporting material can include two phenanthroline ring groups.

The host material in EIL 170 is selected from the compounds represented by Formula J 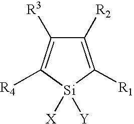
wherein:

R₁ to R₄ are independently hydrogen, alkyl, aryl, or heteroaryl groups; and

X and Y are independently hydrogen, alkyl, aryl, or heteroaryl groups, and can be bonded together to form a saturated or unsaturated ring. Suitably, both R₁ and R₄ include a 5 or 6 membered ring containing a nitrogen atom.

The host material in EIL 170 is selected from the compounds represented by Formula K 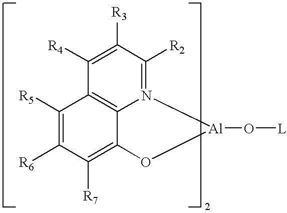
wherein:

R₂ represents an electron donating group;

R₃ and R₄ each independently represent hydrogen or an electron donating group;

R₅, R₆, and R₇ each independently represent hydrogen or an electron accepting group; and

L is an aromatic moiety linked to the aluminum by oxygen that can be substituted such that L has from 7 to 24 carbon atoms.

The host material in EIL 170 can also be selected from the compounds represented by Formula M 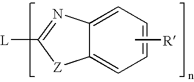
wherein:

n is an integer of 3 to 8;

Z is O, NR or S;

R and R′ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring; and

L is a linkage unit including alkyl, aryl, substituted alkyl, or substituted aryl, which conjugately or unconjugately connects the multiple benzazoles together.

An example of a useful benzazole is 2,2′,2″-(1,3,5-phenylene)tris[1-phenyl-1H-benzimidazole].

Preferred materials for use in EIL 170 include metal chelated oxinoid compounds, various butadiene derivatives as disclosed by Tang in U.S. Pat. No. 4,356,429, various heterocyclic optical brighteners as disclosed by VanSlyke et al. in U.S. Pat. No. 4,539,507, triazines, benzazole derivatives, and phenanthroline derivatives. Silole derivatives, such as 2,5-bis(2′,2″-bipridin-6-yl)-1,1-dimethyl-3,4-diphenyl silacyclopentadiene are also useful in EIL 170. The combination of the aforementioned materials is also useful to form the n-typed doped EIL 170. More preferably, the host material in the n-type doped EIL 170 includes tris(8-hydroxyquinoline)aluminum (Alq), 4,7-diphenyl-1,10-phenanthroline (Bphen), 2,9-dimethyl-4,7-diphenyl-1,10-phenanthroline (BCP), 2,2′-[1,1′-biphenyl]-4,4′-diylbis[4,6-(p-tolyl)- 1,3,5-triazine] (TRAZ), or rubrene, or combinations thereof.

The n-type dopant in the n-type doped EIL 170 is selected from alkali metals, alkali metal compounds, alkaline earth metals, or alkaline earth metal compounds, or combinations thereof. The term “metal compounds” includes organometallic complexes, metal-organic salts, and inorganic salts, oxides and halides. Among the class of metal-containing n-type dopants, Li, Na, K, Rb, Cs, Mg, Ca, Sr, Ba, La, Ce, Sm, Eu, Th, Dy, or Yb, and their compounds, are particularly useful. The materials used as the n-type dopants in the n-type doped EIL 170 also include organic reducing agents with strong electron-donating properties. By “strong electron-donating properties” it is meant that the organic dopant should be able to donate at least some electronic charge to the host to form a charge-transfer complex with the host. Nonlimiting examples of organic molecules include bis(ethylenedithio)-tetrathiafulvalene (BEDT-TTF), tetrathiafulvalene (TTF), and their derivatives. In the case of polymeric hosts, the dopant is any of the above or also a material molecularly dispersed or copolymerized with the host as a minor component. Preferably, the n-type dopant in the n-type doped EIL 170 includes Li, Na, K, Rb, Cs, Mg, Ca, Sr, Ba, La, Ce, Nd, Sm, Eu, Th, Dy, or Yb, or combinations thereof. The n-type doped concentration is preferably in the range of 0.01-20% by volume of this layer. The thickness of the n-type doped EIL 170 is typically less than 200 nm, and preferably in the range of less than 150 nm.

Each of the layers (HIL 130, HTL 140, LEL 150, ETL 160, and EIL 170) in the organic EL units in the OLEDs is formed from small molecule (or nonpolymeric) materials (including fluorescent materials and phosphorescent materials), polymeric LED materials, or inorganic materials, or combinations thereof.

The organic materials in the OLEDs mentioned above are suitably deposited through a vapor-phase method such as thermal evaporation, but are deposited from a fluid, for example, from a solvent with an optional binder to improve film formation. If the material is a polymer, solvent deposition is useful but other methods are used, such as sputtering or thermal transfer from a donor sheet. The material to be deposited by thermal evaporation is vaporized from an evaporation “boat” often including a tantalum material, e.g., as described in U.S. Pat. No. 6,237,529, or is first coated onto a donor sheet and then sublimed in closer proximity to the substrate. Layers with a mixture of materials can use separate evaporation boats or the materials are premixed and coated from a single boat or donor sheet. For full color display, the pixelation of LELs can be needed. This pixelated deposition of LELs is achieved using shadow masks, integral shadow masks, U.S. Pat. No. 5,294,870, spatially defined thermal dye transfer from a donor sheet, U.S. Pat. Nos. 5,688,551, 5,851,709, and 6,066,357, and inkjet method, U.S. Pat. No. 6,066,357.

When light emission is viewed solely through the anode, the cathode 180 includes nearly any conductive material. Desirable materials have effective film-forming properties to ensure effective contact with the underlying organic layer, promote electron injection at low voltage, and have effective stability. Useful cathode materials often contain a low work function metal (<4.0 eV) or metal alloy. One preferred cathode material includes a Mg:Ag alloy as described in U.S. Pat. No. 4,885,221. Another suitable class of cathode materials includes bilayers including a thin inorganic EIL in contact with an organic layer (e.g., organic EIL or ETL), which is capped with a thicker layer of a conductive metal. Here, the inorganic EIL preferably includes a low work function metal or metal salt and, if so, the thicker capping layer does not need to have a low work function. One such cathode includes a thin layer of LiF followed by a thicker layer of Al as described in U.S. Pat. No. 5,677,572. Other useful cathode material sets include, but are not limited to, those disclosed in U.S. Pat. Nos. 5,059,861, 5,059,862, and 6,140,763.

When light emission is viewed through the cathode, cathode 180 should be transparent or nearly transparent. For such applications, metals should be thin or one should use transparent conductive oxides, or include these materials. Optically transparent cathodes have been described in more detail in U.S. Pat. Nos. 4,885,211, 5,247,190, 5,703,436, 5,608,287, 5,837,391, 5,677,572, 5,776,622, 5,776,623, 5,714,838, 5,969,474, 5,739,545, 5,981,306, 6,137,223, 6,140,763, 6,172,459, 6,278,236, 6,284,393, and EP 1 076 368. Cathode materials are typically deposited by thermal evaporation, electron beam evaporation, ion sputtering, or chemical vapor deposition. When needed, patterning is achieved through many well known methods including, but not limited to, through-mask deposition, integral shadow masking, for example as described in U.S. Pat. No. 5,276,380 and EP 0 732 868, laser ablation, and selective chemical vapor deposition.

The description of the device structure and material selection of the OLEDs, shown in FIGS. 5-8, in accordance with the present invention is the same as that described above based on FIGS. 1-4. The only major difference is that the layer fabrication order is altered in FIGS. 5-8. As a result, the cathode 180 is deposited first and is in contact with the substrate 110 in the devices shown in FIGS. 5-8.

Most OLEDs are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

The aforementioned OLEDs prepared in accordance with the present invention are useful in applications. OLED displays or the other electronic devices can include a plurality of the OLEDs as described above.

### EXAMPLES

The following examples are presented for a further understanding of the present invention. In the following examples, the reduction potentials of the materials were measured using an electrochemical analyzer (CHI660 electrochemical analyzer, made by CH Instruments, Inc., Austin, Tex.) with the method as discussed before. During the fabrication of OLEDs, the thickness of the organic layers and the doping concentrations were controlled and measured in situ using calibrated thickness monitors (INFICON IC/5 Deposition Controller, made by Inficon Inc., Syracuse, N.Y.). The EL characteristics of all the fabricated devices were evaluated using a constant current source (KEITHLEY 2400 SourceMeter, made by Keithley Instruments, Inc., Cleveland, Ohio) and a photometer (PHOTO RESEARCH SpectraScan PR 650, made by Photo Research, Inc., Chatsworth, Calif.) at room temperature. The color was reported using Commission Internationale de l'Eclairage (CIE) coordinates. Operational stabilities of the devices were tested at 70° C. by driving a current of 20 mA/cm² through the devices.

### Example 1 (Comparative)

The preparation of a conventional OLED is as follows: A ˜1.1 mm thick glass substrate coated with a transparent ITO conductive layer was cleaned and dried using a commercial glass scrubber tool. The thickness of ITO is about 42 nm and the sheet resistance of the ITO is about 68Ω/square. The ITO surface was subsequently treated with oxidative plasma to condition the surface as an anode. A layer of CFx, 1 nm thick, was deposited on the clean ITO surface as the anode buffer layer by decomposing CHF₃ gas in an RF plasma treatment chamber. The substrate was then transferred into a vacuum deposition chamber for deposition of all other layers on top of the substrate. The following layers were deposited in the following sequence by evaporation from a heated boat under a vacuum of approximately 10⁻⁶ Torr:

1. EL Unit:

a) an HTL, 90 nm thick, including 4,4′-bis[N-(1-naphthyl)-N-phenylamino]biphenyl (NPB);

b) a LEL, 20 nm thick, including TBADN host material doped with 1.5 vol % 2,5,8,11-tetra-t-butylperylene (TBP);

c) an ETL, 10 nm thick, including Alq; and

d) an EIL, 25 nm thick, including Alq doped with about 1.2 vol % lithium.

2. Cathode: approximately 210 nm thick, including Mg:Ag (formed by co-evaporation of about 95 vol % Mg and 5 vol % Ag).

After the deposition of these layers, the device was transferred from the deposition chamber into a dry box (made by VAC Vacuum Atmosphere Company, Hawthorne, Calif.) for encapsulation. The OLED has an emission area of 10 mm².

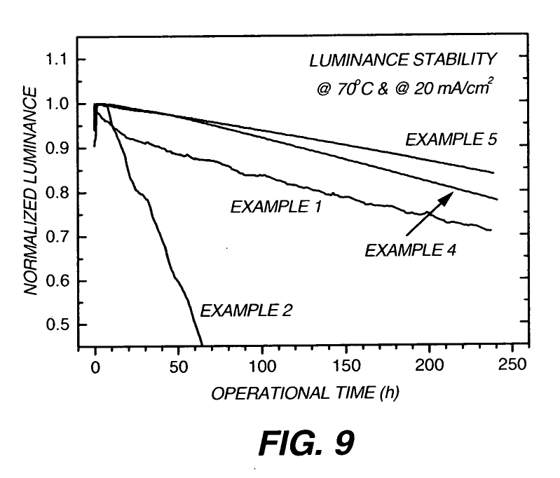

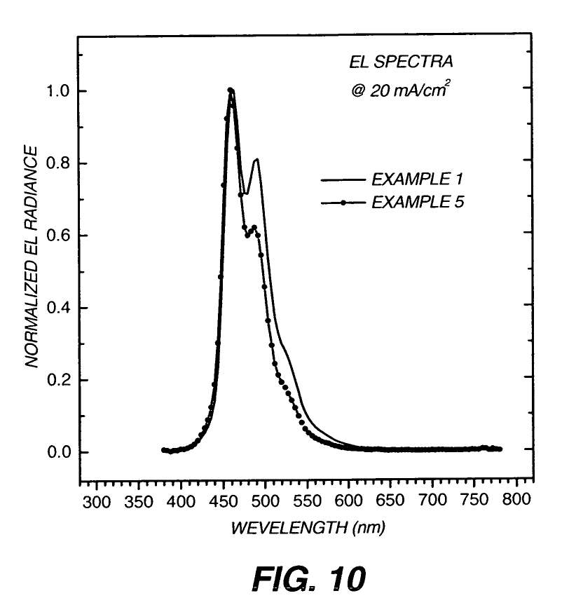

This conventional OLED requires a drive voltage of about 5.5 V to pass 20 mA/cm². Under this test condition, the device has a luminance of 585 cd/m², and a luminous efficiency of about 2.9 cd/A. Its color coordinates are CIEₓ=0.139 and CIE_{y}=0.210, and its emission peak is at 464 nm. The operational stability was measured as T₈₀(70° C.@20 mA/cm²) (i.e. the time at which the luminance has fallen to 80% of its initial value after being operated at 70° C. and at 20 mA/cm²). Its T₈₀(70° C.@20 mA/cm²) is about 140 hours. The EL performance data are summarized in Table 1, its normalized luminance vs. operational time, tested at 70° C. and at 20 mA/cm², is shown in FIG. 9, and its normalized EL spectrum is shown in FIG. 10.

This is a conventional device. It is obvious that the materials in the LEL and in the ETL are different from each other in terms of the molecular structures. The ETL contributes a small portion of green emission to the whole spectrum as is indicated in FIG. 10.

### Example 2 (Comparative)

Another OLED was constructed as the same as that in Example 1, except that layers c and d were changed as:

c) an ETL, 10 nm thick, including Bphen; and

d) an EIL, 25 nm thick, including Bphen doped with about 1.2 vol % lithium.

This OLED requires a drive voltage of about 4.1 V to pass 20 mA/cm². Under this test condition, the device has a luminance of 633 cd/m², and a luminous efficiency of about 3.2 cd/A. Its color coordinates are CIEₓ=0.135 and CIE_{y}=0.187, and its emission peak is at 464 nm. Its T₈₀(70° C.@20 mA/cm²) is about 29 hours. The EL performance data are summarized in Table 1, and its normalized luminance vs. operational time, tested at 70° C. and at 20 mA/cm², is shown in FIG. 9.

In this device, it is obvious that the materials in the LEL and in the ETL are different from each other in terms of the molecular structures. Although this device has low drive voltage, high luminous efficiency, and improved blue color, the operational stability is very short and unacceptable for real applications.

### Example 3 (Comparative)

Another OLED was constructed as the same as that in Example 1, except that the EL unit is:

a) an HTL, 75 nm thick, including NPB;

b) a LEL, 20 nm thick, including TBADN host material doped with 1.5 vol % TBP;

c) an ETL, 5 nm thick, including TBADN; and

d) an EIL, 30 nm thick, including Alq doped with about 1.2 vol % lithium.

This OLED requires a drive voltage of about 5.3 V to pass 20 mA/cm². Under this test condition, the device has a luminance of 365 cd/m², and a luminous efficiency of about 1.8 cd/A. Its color coordinates are CIEₓ=0.135 and CIE_{y}=0.166, and its emission peak is at 461 nm. Its T₈₀(70° C.@20 mA/cm²) is about 500 hours. The EL performance data are summarized in Table 1.

In this device, both the host materials in the LEL and the material in the ETL are TBADN. Although this device has very effective operational stability, its luminous efficiency is very low.

### Example 4 (Inventive)

An OLED, in accordance with the present invention, was constructed as the same as that in Example 3, except that the 5 nm thick ETL (layer c) includes Material F-3, instead of Alq.

This OLED requires a drive voltage of about 4.8 V to pass 20 mA/cm². Under this test condition, the device has a luminance of 587 cd/m², and a luminous efficiency of about 2.9 cd/A. Its color coordinates are CIEₓ=0.135 and CIE_{y}=0.169, and its emission peak is at 461 nm. Its T₈₀(70° C.@20 mA/cm²) is about 220 hours. The EL performance data are summarized in Table 1, and its normalized luminance vs. operational time, tested at 70° C. and at 20 mA/cm², is shown in FIG. 9.

In this device, both the host material in the LEL and the material in the ETL are anthracene derivatives. The reduction potential of TBADN and F-3 were measured as about −1.90 V and −1.78 V vs. SCE in the 1:1 MeCN/toluene organic solvent system, respectively. Therefore, the reduction potential of F-3 is about 0.12 V greater than that of TBADN. Moreover, the oxidation potential of TBADN and F-3 were measured as about 1.25 V and 1.29 V vs. SCE in the 1:1 MeCN/toluene organic solvent system, respectively. Therefore, the oxidation potential of F-3 is about 0.04 V greater than that of TBADN. Comparing to the device in Example 1, this device in Example 4 has lower drive voltage, comparable luminous efficiency, better operational stability, and purer blue color.

### Example 5 (Inventive)

Another OLED, in accordance with the present invention, was constructed as the same as that in Example 3, except that the 5 nm thick ETL (layer c) includes Material F-3 doped with about 1.2 vol % lithium, instead of Alq.

This OLED requires a drive voltage of about 4.2 V to pass 20 mA/cm². Under this test condition, the device has a luminance of 577 cd/m², and a luminous efficiency of about 2.9 cd/A. Its color coordinates are CIEₓ=0.136 and CIE_{y}=0.158, and its emission peak is at 460 nm. Its T₈₀(70° C.@20 mA/cm ²) is projected as about 300 hours. The EL performance data are summarized in Table 1, its normalized luminance vs. operational time, tested at 70° C. and at 20 mA/cm², is shown in FIG. 9, and its normalized EL spectrum is shown in FIG. 10.

In this device, both the host material in the LEL and the material in the ETL are anthracene derivatives. With lithium being incorporated in the ETL, the drive voltage, the operational stability, and the color have been further improved compared to those of the device in Example 4.

### Example 6 (Inventive)

An OLED, in accordance with the present invention, was constructed in the same manner as Example 3, except that the 5 nm thick ETL (layer c) includes Material G-1, instead of Alq.

This OLED requires a drive voltage of about 4.9 V to pass 20 mA/cm². Under this test condition, the device has a luminance of 570 cd/m², and a luminous efficiency of about 2.9 cd/A. Its color coordinates are CIEₓ=0.135 and CIE_{y}=0.162, and its emission peak is at 462 nm. Its T₈₀(70° C@20 mA/cm 2) is greater than 220 hours. The EL performance data are summarized in Table 1.

In this device, both the host material in the LEL and the material in the ETL are anthracene derivatives. The reduction potential of TBADN and G-1 were measured as about −1.90 V and −1.86 V vs. SCE in the 1:1 MeCN/toluene organic solvent system, respectively. Therefore, the reduction potential of G-1 is about 0.04 V greater than that of TBADN. Moreover, the oxidation potential of TBADN and G-1 were measured as about 1.25 V and 1.31 V vs. SCE in the 1:1 MeCN/toluene organic solvent system, respectively. Therefore, the oxidation potential of G-1 is about 0.06 V greater than that of TBADN. Comparing to the device in Example 1, this device in Example 6 has lower drive voltage, comparable luminous efficiency, better operational stability, and purer blue color.

### Example 7 (Inventive)

Another OLED, in accordance with the present invention, was constructed as the same as that in Example 3, except that the 5 nm thick ETL (layer c) includes Material G-1 doped with about 1.2 vol % lithium, instead of Alq.

This OLED requires a drive voltage of about 4.5 V to pass 20 mA/cm². Under this test condition, the device has a luminance of 623 cd/m², and a luminous efficiency of about 3.1 cd/A. Its color coordinates are CIEₓ=0.136 and CIE_{y}=0.163, and its emission peak is at 462 nm. Its T₈₀(70° C.@20 mA/cm 2) is greater than 220 hours. The EL performance data are summarized in Table 1.

In this device, both the host material in the LEL and the material in the ETL are anthracene derivatives. With lithium being incorporated in the ETL, the drive voltage and the luminance efficiency have been further improved compared to those of the device in Example 6.

TABLE 1

| Example(Type) | | | | | | | |
|---|---|---|---|---|---|---|---|
| (EL measured | | | Luminous | | | Emission | |
| @ RT and | Voltage | Luminance | Efficiency | CIE x | CIE y | Peak | T₈₀(70° C.) |
| 20 mA/cm²) | (V) | (cd/m²) | (cd/A) | (1931) | (1931) | (nm) | (Hrs) |
| 1 (Comparative) | 5.5 | 585 | 2.9 | 0.139 | 0.210 | 464 | 140 |
| 2 (Comparative) | 4.1 | 633 | 3.2 | 0.135 | 0.187 | 464 | 29 |
| 3 (Comparative) | 5.3 | 365 | 1.8 | 0.135 | 0.166 | 461 | ˜500 |
| 4 (Inventive) | 4.8 | 587 | 2.9 | 0.135 | 0.169 | 461 | 220 |
| 5 (Inventive) | 4.2 | 577 | 2.9 | 0.136 | 0.158 | 460 | ˜300 |
| 6 (Inventive) | 4.9 | 570 | 2.9 | 0.135 | 0.162 | 462 | >220 |
| 7 (Inventive) | 4.5 | 623 | 3.1 | 0.136 | 0.163 | 462 | >220 |

The invention has been described in detail with particular reference to certain preferred embodiments thereof, but it will be understood that variations and modifications can be effected within the spirit and scope of the invention.

PARTS LIST

| | |
|---|---|
| 100 | OLED |
| 110 | substrate |
| 120 | anode |
| 130 | hole-injecting layer (HIL) |
| 140 | hole-transporting layer (HTL) |
| 150 | light-emitting layer (LEL) |
| 160 | electron-transporting layer (ETL) |
| 170 | electron-injecting layer (EIL) |
| 180 | cathode |
| 191 | electrical conductors |
| 192 | voltage/current source |
| 200 | OLED |
| 300 | OLED |
| 400 | OLED |
| 500 | OLED |
| 600 | OLED |
| 700 | OLED |
| 800 | OLED |

1. An organic light-emitting device (OLED), comprising:
a) an anode;
b) a cathode;
c) a light-emitting layer disposed between the anode and the cathode, wherein the light-emitting layer includes a dominant host and a dopant; and
d) an electron-transporting layer disposed in direct contact with the light-emitting layer on the cathode side, wherein the electron-transporting layer includes an electron-transporting material having the same chromophore as that of the dominant host in the light-emitting layer, wherein the electron-transporting material constitutes more than 50% by volume of the electron-transporting layer, and wherein the electron-transporting material has a greater reduction potential than that of the dominant host in the light-emitting layer.

2. The OLED of claim 1 wherein the dominant host in the light-emitting layer is an anthracene derivative and wherein the electron-transporting material in the electron-transporting layer includes a different anthracene derivative.

3. The OLED of claim 2 wherein the different anthracene derivative in the electron-transporting layer is selected from the materials represented by 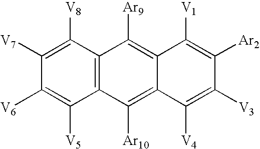
wherein:
Ar₂, Ar₉, and Ar₁₀ independently represent an aryl group; and
v₁, v₃, v₄, v₅, v₆, v₇, and v₈ independently represent hydrogen or a substituent.

4. The OLED of claim 3 wherein the different anthracene derivative in the electron-transporting layer is selected from the materials represented by:

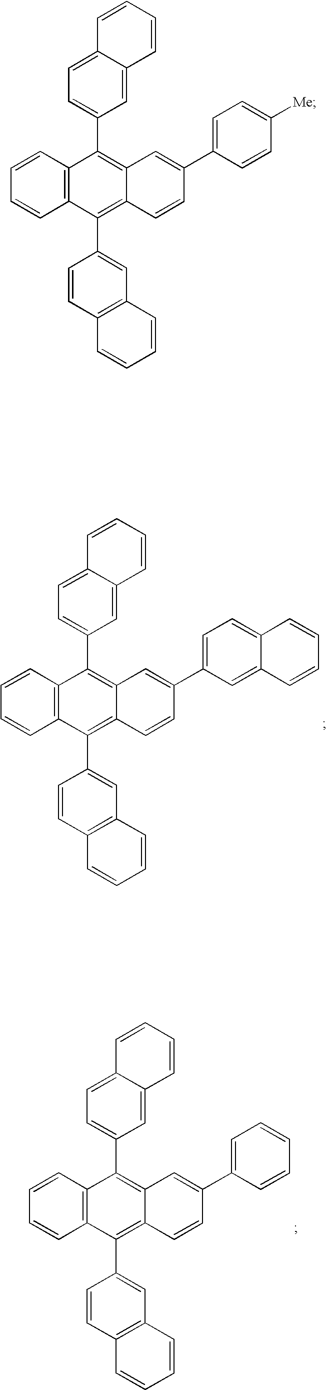

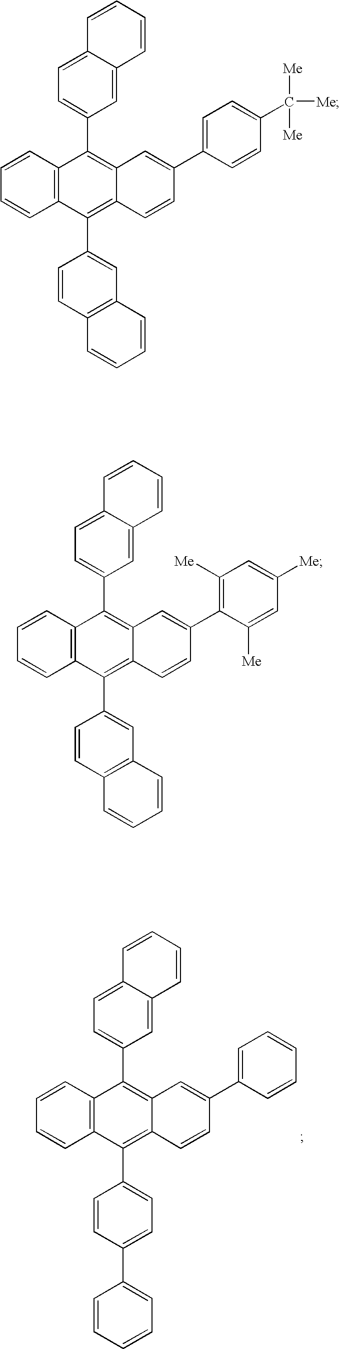

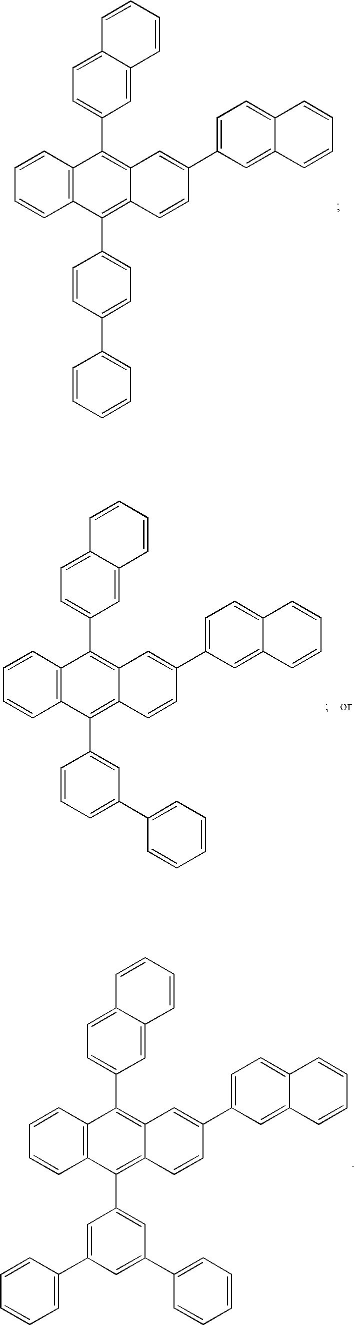

5. The OLED of claim 2 wherein the different anthracene derivative in the electron-transporting layer is selected from the materials represented by 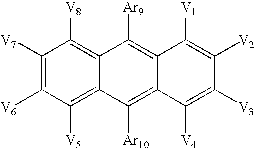
wherein:
Ar₉, and Ar₁₀ independently represent an aryl group; and
v₁, v₂, v₃, v₄, v₅, v₆, v₇, and v₈ independently represent hydrogen or a substituent.

6. The OLED of claim 5 wherein the different anthracene derivative in the electron-transporting layer is selected from the materials represented by:

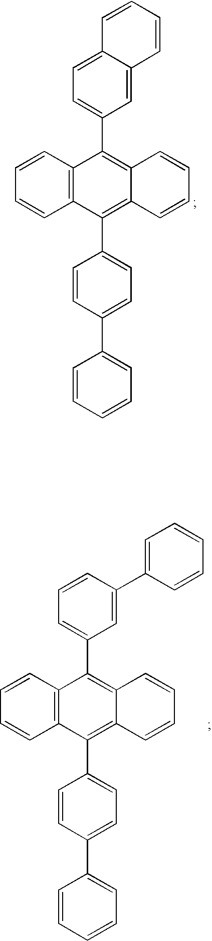

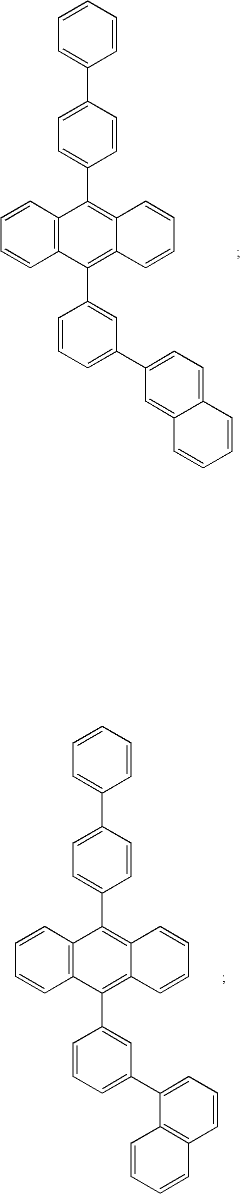

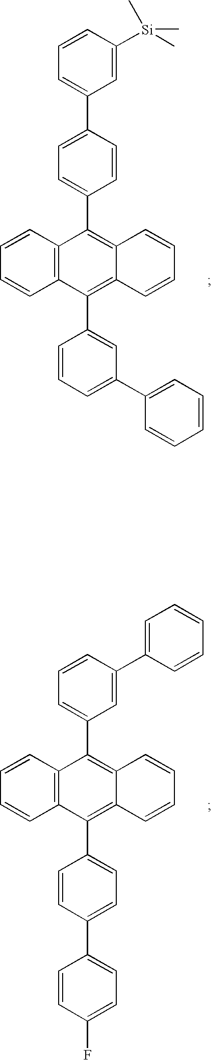

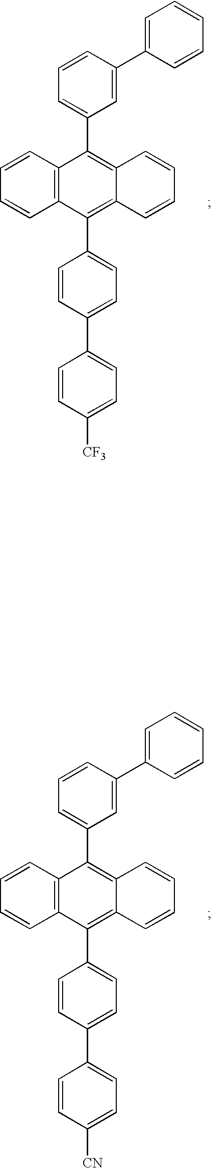

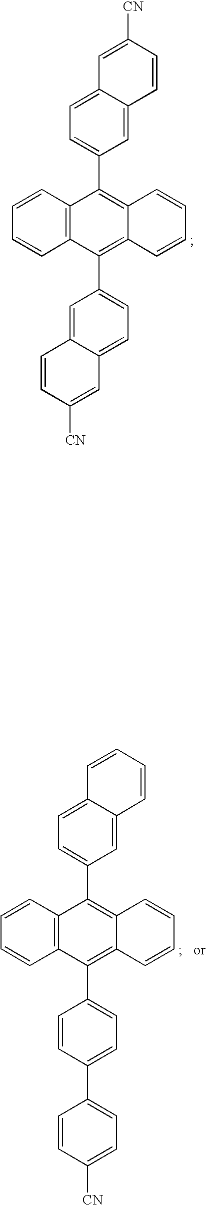

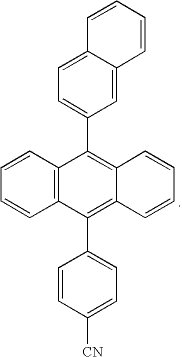

7. The OLED of claim 2 wherein the dominant host in the light-emitting layer is 2-(1,1-dimethyethyl)-9,10-bis(2-naphthalenyl)anthracene (TBADN) represented by 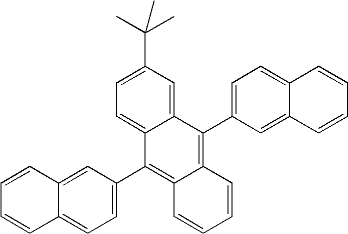
and wherein the material in the electron-transporting layer includes the different anthracene derivative represented by:

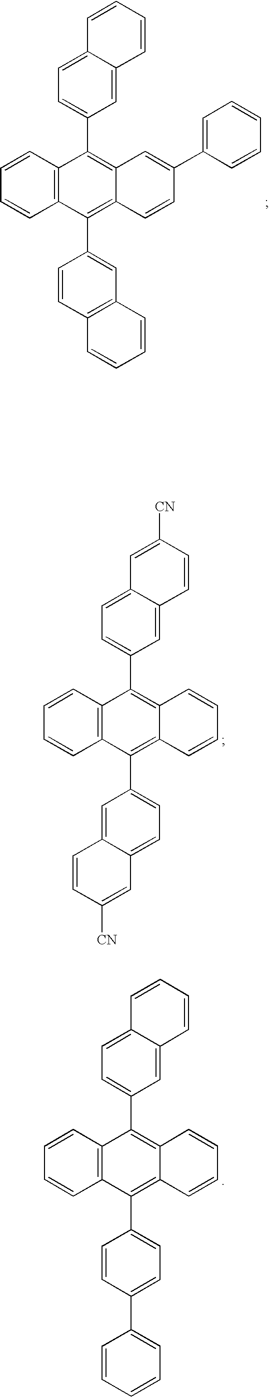

8. The OLED of claim 2 wherein the dominant host in the light-emitting layer is 9,10-bis(2-naphthyl)anthracene (AD-N) represented by 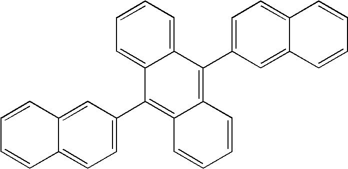
and wherein the material in the electron-transporting layer includes the different anthracene derivative represented by:

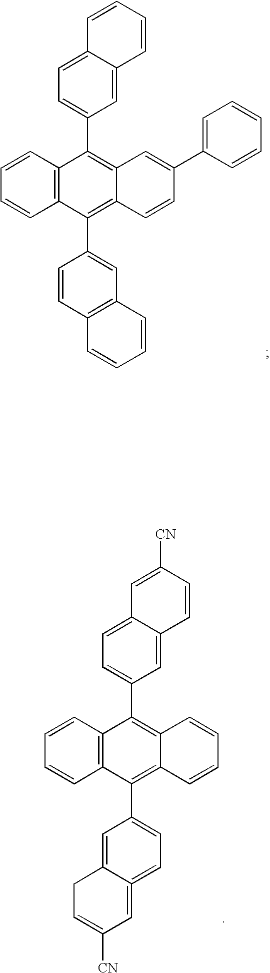

9. The OLED of claim 1 wherein the dominant host in the light-emitting layer is a tetracene derivative and wherein the material in the electron-transporting layer includes a different tetracene derivative.

10. The OLED of claim 9 wherein the different tetracene derivative in the electron-transporting layer is selected from the materials represented by 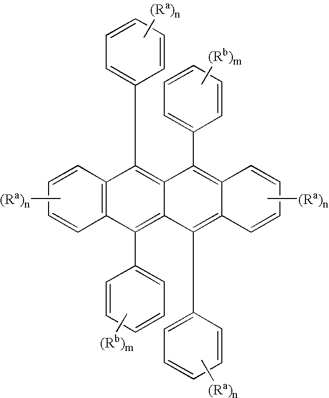
wherein:
R^{a} and R^{b} are substituent groups;
n is selected from 0-4; and
m is selected from 0-5.

11. The OLED of claim 10 wherein the different tetracene derivative in the electron-transporting layer is selected from the materials represented by:

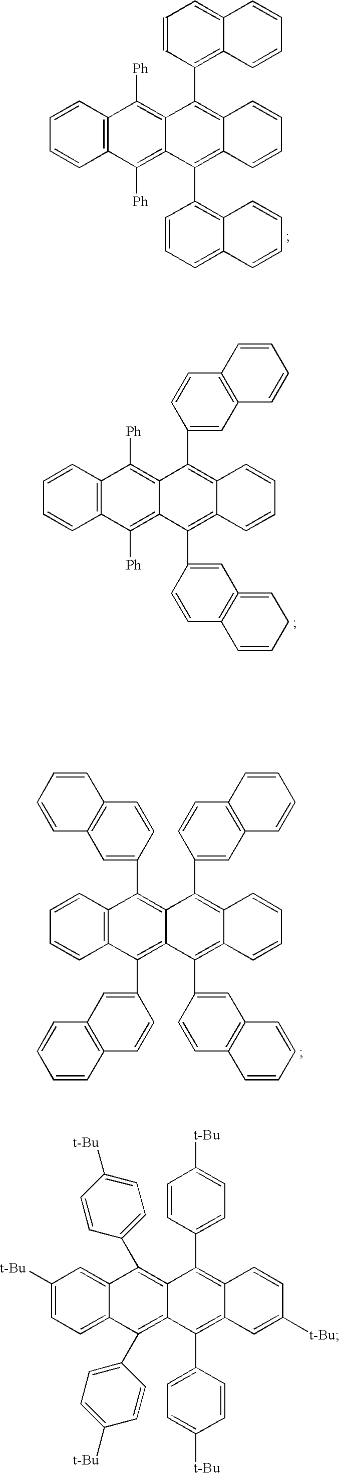

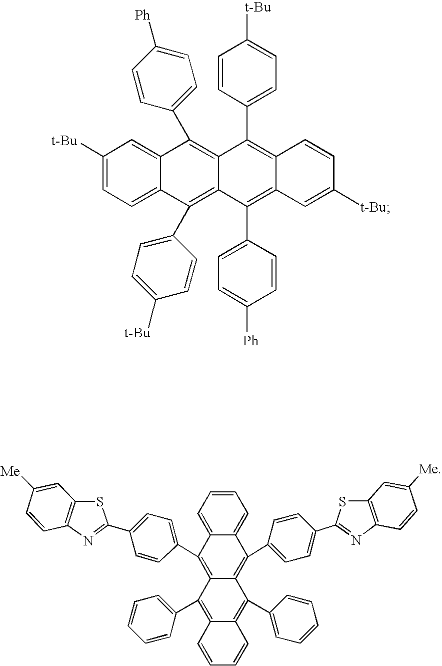

12. The OLED of claim 9 wherein the dominant host in the light-emitting layer is rubrene represented by 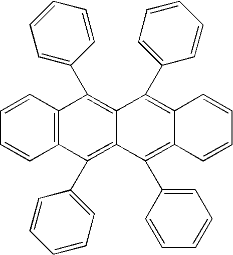
and wherein the material in the electron-transporting layer includes the different tetracene derivative represented by:

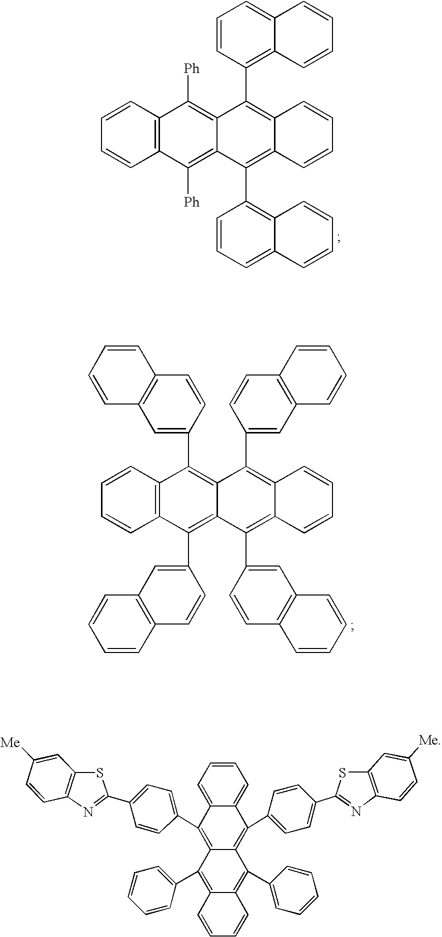

13. The OLED of claim 1 wherein the electron-transporting layer can include a dopant having a work function lower than 4.0 eV.

14. The OLED of claim 13 wherein the dopant in the electron-transporting layer includes alkali metals, alkali metal compounds, alkaline earth metals, or alkaline earth metal compounds.

15. The OLED of claim 13 wherein the dopant in the electron-transporting layer includes Li, Na, K, Rb, Cs, Mg, Ca, Sr, Ba, La, Ce, Nd, Sm, Eu, Th, Dy, or Yb.

16. The OLED of claim 13 wherein the concentration of the dopant is in the range from 0.01% to 20% by volume of the electron-transporting layer.

17. The OLED of claim 1 wherein the electron-transporting layer has the thickness in the range of from 1 nm to 70 nm.

18. The OLED of claim 1 wherein the device emits a red, green, blue, or white color.

19. An OLED display including a plurality of OLEDs according to claim 1.
